(19) United States
(12) Patent Application Publication
(10) Pub. No.: US 2026/0140234 A1
(43) Pub. Date: May 21, 2026

(54) OPTICAL SENSOR FOR SENSING BIOMETRIC SIGNAL AND ELECTRONIC DEVICE INCLUDING SAME

(71) Applicant: Samsung Electronics Co., Ltd., Suwon-si (KR)

(72) Inventors: Jeahyuck LEE, Suwon-si (KR); Joongwoo AHN, Suwon-si (KR); Ariadna SCHUCK, Suwon-si (KR); Younghyun KIM, Suwon-si (KR)

(21) Appl. No.: 19/406,133

(22) Filed: Dec. 2, 2025

Related U.S. Application Data
(63) Continuation of application No. PCT/KR2025/016062, filed on Oct. 13, 2025.

(30) Foreign Application Priority Data
Nov. 18, 2024 (KR) 10-2024-0163875
Mar. 12, 2025 (KR) 10-2025-0032192

(51) Int. Cl. G01S 7/481; G02B 6/293; G06V 40/13; H01S 5/02255; H01S 5/0239; H01S 5/068; H01S 5/40

(52) U.S. Cl. CPC G01S 7/4813; G01S 7/4815; G02B 6/29317; H01S 5/02255; H01S 5/0239; H01S 5/06821; H01S 5/4087; G06V 40/1318

(57) ABSTRACT

An optical sensor for detecting a biometric signal is provided. The optical sensor includes a substrate including a groove, a laser diode which is inserted into the groove, and includes an active layer, and a plurality of lights of different wavelengths that are emitted from a plurality of light-emitting points of the active layer, a plurality of waveguides which are arranged inside the substrate, and are configured to guide the plurality of lights emitted from the active layer of the laser diode, a plurality of first optical lines which are arranged inside the substrate, and of which one end is connected to the plurality of waveguides and the other end is connected to a plurality of light output structures, and which transmit the plurality of lights guided along the plurality of waveguides to the plurality of light output structures, second optical lines which are arranged inside the substrate, and are branched from one of the plurality of first optical lines, and a light detecting element which is arranged on the substrate, and detects light transmitted along the second optical lines, wherein the laser diode is configured to be inserted into the groove such that heights of the plurality of light-emitting points of the active layer are respectively aligned with the heights of the plurality of waveguides.

### CROSS-REFERENCE TO RELATED APPLICATION(S)

This application is a continuation application, claiming priority under 35 U.S.C. § 365(c), of an International application No. PCT/KR2025/016062, filed on Oct. 13, 2025, which is based on and claims the benefit of a Korean patent application number 10-2024-0163875, filed on Nov. 18, 2024, in the Korean Intellectual Property Office, and of a Korean patent application number 10-2025-0032192, filed on Mar. 12, 2025, in the Korean Intellectual Property Office, the disclosure of each of which is incorporated by reference herein in its entirety.

### TECHNICAL FIELD

The disclosure relates to an optical sensor for detecting a biometric signal of an object for inspection by a non-invasive method, and an electronic device including the same.

### BACKGROUND ART

As methods for measuring the content of a component of a human body (e.g.: a component inside blood), there may be an invasive method and a non-invasive method. An invasive measurement method may proceed by a process of extracting blood with a lancet in a portion to take a blood sample, and putting the blood into an inspection sheet or a diagnostic reagent. In the case of a non-invasive measurement method, a blood sampling process is not required, and thus blood sugar can be measured relatively swiftly.

The above information is presented as background information only to assist with an understanding of the disclosure. No determination has been made, and no assertion is made, as to whether any of the above might be applicable as prior art with regard to the disclosure.

### DISCLOSURE OF INVENTION

Aspects of the disclosure are to address at least the above-mentioned problems and/or disadvantages and to provide at least the advantages described below. Accordingly, an aspect of the disclosure is to provide an optical sensor for detecting a biometric signal of an object for inspection by a non-invasive method, and an electronic device including the same.

Additional aspects will be set forth in part in the description which follows and, in part, will be apparent from the description, or may be learned by practice of the presented embodiments.

### Solution to Problem

In accordance with an aspect of the disclosure, an optical sensor for sensing a biometric signal is provided. The optical sensor includes a substrate including a groove, a laser diode which is inserted into the groove, and includes an active layer, and a plurality of lights of different wavelengths that are emitted from a plurality of light-emitting points of the active layer, a plurality of waveguides which are arranged inside the substrate, and are configured to guide the plurality of lights emitted from the active layer of the laser diode, a plurality of first optical lines which are arranged inside the substrate, and of which one end is connected to the plurality of waveguides and the other end is connected to a plurality of light output structures, and which transmit the plurality of lights guided along the plurality of waveguides to the plurality of light output structures, second optical lines which are arranged inside the substrate, and are branched from one of the plurality of first optical lines, and a light detecting element which is arranged on the substrate, and detects light transmitted along the second optical lines, wherein the laser diode is configured to be inserted into the groove such that the heights of the plurality of light-emitting points of the active layer are respectively aligned with the heights of the plurality of waveguides.

In accordance with another aspect of the disclosure, an optical sensor for sensing a biometric signal is provided. The optical sensor includes a substrate including a plurality of grooves, a plurality of laser diodes which are respectively inserted into the plurality of grooves, and a plurality of light detecting elements which are arranged on a top surface of the substrate, and detect some lights among a plurality of lights emitted from the plurality of laser diodes. Each of the plurality of laser diodes includes an active layer which emits lights of different wavelengths. The substrate includes a plurality of waveguides which are arranged to be adjacent to the plurality of grooves inside the substrate, and guide lights respectively emitted from the front surfaces of the plurality of laser diodes to the plurality of light detecting elements, a plurality of first optical lines which are arranged inside the substrate, and are respectively connected to the plurality of waveguides and guide lights transmitted along the plurality of waveguides to a plurality of light output structures, and a plurality of second optical lines which are arranged inside the substrate, and are branched from the plurality of first optical lines and guide lights to the light detecting elements.

In accordance with another aspect of the disclosure, an optical sensor for sensing a biometric signal is provided. The optical sensor includes a laser diode which emits a plurality of lights, a substrate including a groove into which the laser diode is inserted, a plurality of waveguides which are arranged inside the substrate, and guide the plurality of lights, a plurality of light output structures which are arranged inside the substrate, and emit the plurality of lights guided by the plurality of waveguides toward an object for inspection, and a lens which is arranged to be spaced apart from the substrate, and focuses the plurality of lights emitted from the plurality of light output structures on the object for inspection.

In accordance with another aspect of the disclosure, an electronic device is provided. The electronic device includes a housing including a light transmitting material, an optical sensor which is arranged on the inner side of the housing and emits a light toward an object for inspection on the outer side of the housing, an optical interface which introduces the light emitted from the optical sensor into the object for inspection, and a photodiode which detects a light reflected on the object for inspection, wherein the optical sensor includes a laser diode which includes an active layer that emits light of different wavelengths in a defined wavelength band, a substrate which includes a groove into which the laser diode is inserted, a plurality of waveguides which respectively guides light emitted from a front surface of the laser diode, a plurality of first optical lines which are respectively connected to the plurality of waveguides and guides light transmitted along the plurality of waveguides to a plurality of light output structures, and second optical lines branched from at least one first optical line among the plurality of first optical lines, a light detecting element which is arranged on the substrate and detects light transmitted along the first optical lines and light transmitted along the second optical lines, a Mach-Zehnder interferometer which is arranged between the second optical lines and the light detecting element, and measures the strength and a defined wavelength of the light transmitted along the second optical lines, and a thermal optical phase shifter which is arranged on the first optical lines and is configured to thermally control light transmitted to an outputter to change the strength of the light emitted from the outputter, and wherein the substrate includes a support on which the laser diode rests such that the height of the active layer of the laser diode is aligned with the heights of the plurality of waveguides.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram of an electronic device that can perform operations explained according to an embodiment of the disclosure;

FIG. 2 is a block diagram illustrating an example including a component that can sense a biometric signal by a non-invasive method of an electronic device according to an embodiment of the disclosure;

FIG. 3 is a block diagram illustrating an optical sensor according to an embodiment of the disclosure;

FIG. 4 is a perspective view illustrating an optical sensor according to an embodiment of the disclosure;

FIG. 5 is a plan view of an optical sensor, and is a diagram illustrating an example of partitioning the optical sensor into first, second, third, and fourth areas according to an embodiment of the disclosure;

FIG. 6 is a plan view illustrating an optical sensor according to an embodiment of the disclosure;

FIG. 7 is a diagram illustrating an example wherein a light source is coupled to a substrate of an optical sensor according to an embodiment of the disclosure;

FIG. 8 is a plan view illustrating an example wherein a light source is coupled to a substrate of an optical sensor according to an embodiment of the disclosure;

FIG. 9 illustrates an example wherein a light source is coupled to a substrate of an optical sensor, and is a cross-sectional view illustrated along the B-B′ line displayed in FIG. 8 according to an embodiment of the disclosure;

FIG. 10 illustrates an example wherein a light source is coupled to a substrate of an optical sensor, and is a cross-sectional view illustrated along the C-C′ line displayed in FIG. 8 according to an embodiment of the disclosure;

FIG. 11 is a diagram that enlarged a part of a light source according to an embodiment of the disclosure;

FIG. 12 is a diagram illustrating an example wherein a light source is coupled to a substrate according to an embodiment of the disclosure;

FIG. 13 is a diagram illustrating components formed on a substrate of an optical sensor according to an embodiment of the disclosure;

FIG. 14 is a graph illustrating an example wherein a light-emitting wavelength of a light source changes according to a temperature according to an embodiment of the disclosure;

FIG. 15 is a diagram illustrating a Mach-Zehnder interferometer formed on a substrate of an optical sensor according to an embodiment of the disclosure;

FIG. 16 is a diagram illustrating the E1 and E2 parts displayed in FIG. 15 which are parts of a Mach-Zehnder interferometer formed on a substrate of an optical sensor according to an embodiment of the disclosure;

FIG. 17 is a graph illustrating values measured through a Mach-Zehnder interferometer formed on a substrate of an optical sensor according to an embodiment of the disclosure;

FIG. 18 is a graph illustrating spectrums for each temperature measured through a Mach-Zehnder interferometer according to an embodiment of the disclosure;

FIG. 19 is a diagram illustrating light detecting elements of an optical sensor according to an embodiment of the disclosure;

FIG. 20 is a diagram illustrating light detecting elements of an optical sensor, and is a cross-sectional view illustrated along the G-G′ line displayed in FIG. 19 according to an embodiment of the disclosure;

FIG. 21 is a diagram illustrating a thermal optical phase shifter of an optical sensor according to an embodiment of the disclosure; and

FIG. 22 is a diagram illustrating a plurality of light output structures included in a substrate according to an embodiment of the disclosure.

Throughout the drawings, it should be noted that like reference numbers are used to depict the same or similar elements, features, and structures.

### MODE FOR INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In addition, one or more embodiments according to the disclosure may be modified in various different forms, and the scope of the technical idea of the disclosure is not limited to the embodiments below. Rather, these embodiments are provided to make the disclosure more sufficient and complete, and to fully convey the technical idea of the disclosure to those skilled in the art.

Also, in the disclosure, expressions such as “have,” “may have,” “include,” and “may include” denote the existence of such characteristics (e.g.: elements such as numbers, functions, operations, and components), and do not exclude the existence of additional characteristics.

In addition, in the disclosure, the expressions “A or B,” “at least one of A and/or B,” or “one or more of A and/or B” and the like may include all possible combinations of the listed items. For example, “A or B,” “at least one of A and B,” or “at least one of A or B” may refer to all of the following cases: (1) including at least one A, (2) including at least one B, or (3) including at least one A and at least one B.

Further, the expressions “first,” “second,” and the like used in the disclosure may describe various elements regardless of any order and/or degree of importance. Also, such expressions are used only to distinguish one element from another element, and are not intended to limit the elements.

Also, the expression “configured to” used in the disclosure may be interchangeably used with other expressions such as “suitable for,” “having the capacity to,” “designed to,” “adapted to,” “made to,” and “capable of,” depending on cases. Meanwhile, the term “configured to” may not necessarily mean that a device is “specifically designed to” in terms of hardware.

Further, in the disclosure, ‘a module’ or ‘a part’ may perform at least one function or operation, and may be implemented as hardware or software, or as a combination of hardware and software. Also, a plurality of ‘modules’ or ‘parts’ may be integrated into at least one module and implemented as at least one processor, excluding ‘a module’ or ‘a part’ that needs to be implemented as specific hardware.

Meanwhile, various elements and areas in the drawings were illustrated schematically. Accordingly, the technical idea of the disclosure is not limited by the relative sizes or intervals illustrated in the accompanying drawings.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

Hereinafter, one or more embodiments according to the disclosure will be described in detail with reference to the accompanying drawings, such that those having ordinary skill in the art to which the disclosure belongs can easily carry out the disclosure.

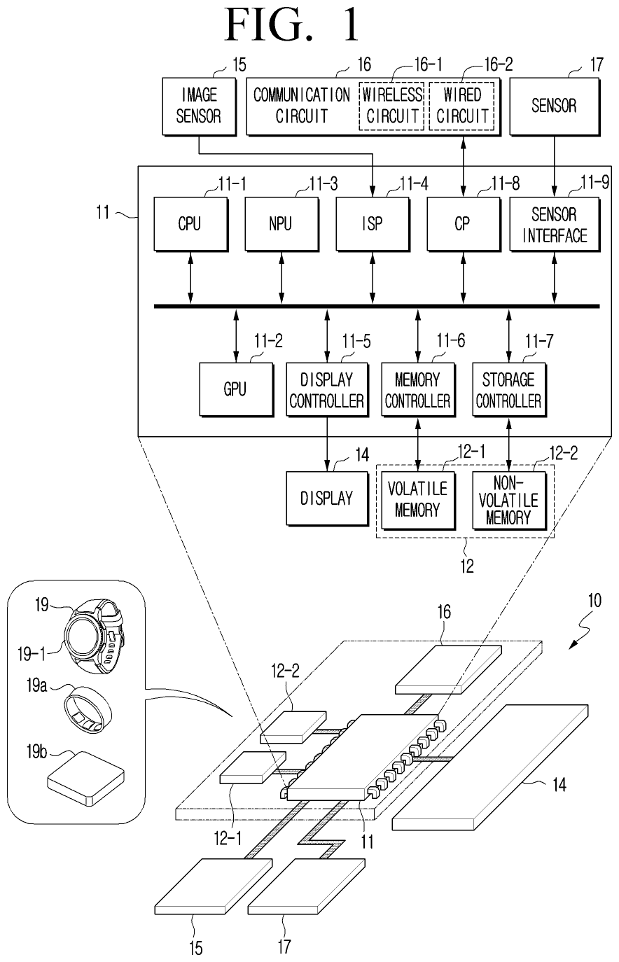

FIG. 1 is a block diagram of an electronic device that can perform operations explained in the disclosure according to an embodiment of the disclosure.

Referring to FIG. 1, an electronic device 10 may be one of electronic devices in various forms such as a smart watch 19, a smart ring 19a, and other similar computing devices (not shown). Meanwhile, the components illustrated in FIG. 1, their relations, and their functions are merely exemplary ones, and do not limit the implementations explained or claimed in the disclosure. The electronic device 10 may be referred to as a wearable device (e.g.: the smart watch 19 and the smart ring 19a), a device of a small patch type that can be attached on a human body (19b in FIG. 1), a mobile device, a user device, a multifunctional device, a portable device, or a server.

According to an embodiment, the electronic device 10 may include components including at least one processor 11 (referred to as a processor 11 hereinafter), at least one memory 12 (referred to as memory 12 hereinafter), at least one display 14 (referred to as a display 14 hereinafter), at least one image sensor 15 (referred to as an image sensor 15 hereinafter), at least one communication circuit 16 (referred to as a communication circuit 16 hereinafter), and/or at least one sensor 17 (referred to as a sensor 17 hereinafter). However, the components above are merely exemplary ones. For example, the electronic device 10 may include other components (e.g.: power management integrated circuitry (PMIC), audio processing circuitry, an antenna, a rechargeable battery, or an input/output interface). For example, some components may be omitted from the electronic device 10. For example, some components may be integrated as one component.

According to an embodiment, the processor 11 may be implemented as one or more integrated circuit (or circuitry) (IC) chips, and perform various types of data processing. The processor 11 may include at least one electric circuit, and perform distributive processing of instructions (or programs, data) stored in the memory 12 individually or collectively. The processor 11 may include a processor assembly including one or more processing circuits. The processor 11 may include any operative processing circuit for controlling the performance and operations of one or more components (e.g.: the memory 12, the display 14, the image sensor 15, the communication circuit 16, and the sensor 17) of the electronic device 10. For example, the processor 11 (e.g.: an application processor (AP)) may be implemented as a system on chip (SoC) (e.g., one chip or a chip set). For example, the processor 11 may be implemented as a plurality of cores (or at least one core circuit), a plurality of chips, or a plurality of chip sets. For example, the processor 11 may include one or more processing circuits. For example, the processor 11 may include one or more processing circuits that are constituted to individually and/or collectively perform several functions in the disclosure. As an unlimited example, at least a part of the processor 11 may be included in a first chip of the electronic device 10, and at least another part of the processor 11 may be included in a second chip of the electronic device 10 different from the first chip of the electronic device 10.

For example, the processor 11 may include a central processing unit (CPU) 11-1, a graphics processing unit (GPU) 11-2, a neural processing unit (NPU) 11-3, an image signal processor (ISP) 11-4, a display controller 11-5, a memory controller 11-6, a storage controller 11-7, a communication processor (CP) 11-8, and a sensor interface 11-9. However, these components of the processor 11 are merely exemplary ones. For example, the processor 11 may further include other components. For example, some components of the processor 11 may be omitted from the processor 11. For example, some components of the processor 11 may be included as separate components of the electronic device 10 outside the processor 11. For example, some components of the processor 11 (e.g.: the memory controller 11-6) may be included in the other components (e.g.: at least a portion of the memory 12, the interface (e.g.: can be used to connect to the at least one component of the electronic device 10), the display 14, and/or the image sensor 15).

According to an embodiment, the processor 11 may cause the other components of the electronic device 10 to perform various operations by executing the instructions stored in the memory 12. The CPU 11-1 (or a central processing circuit) may be constituted to control the components of the processor 11 based on execution of instructions stored in the memory 12 (e.g.: volatile memory 12-1 and/or non-volatile memory 12-2). The GPU 11-2 (or a graphics processing circuit) may be constituted to execute parallel operations (e.g.: rendering). The NPU 11-3 (or a neural processing circuit, or an artificial intelligence (AI) chip) may be constituted to execute operations for an artificial intelligence model (e.g.: convolution computations). The IPS 11-4 (or an image signal processing circuit) may be constituted to process a raw image obtained through the image sensor 15 in a format appropriate for the components inside the electronic device 10 or the components of the processor 11. The display controller 11-5 (or a display control circuit, or a display processing unit (DPU)) may be constituted to process an image obtained from the CPU 11-1, the GPU 11-2, the ISP 11-4, or the memory 12 (e.g.: the volatile memory 12-1) in a format appropriate for the display 14. The memory controller 11-6 (or a memory control circuit) may be constituted to control reading of data from the volatile memory 12-1 and recording of the data in the volatile memory 12-1. The storage controller 11-7 (or a storage control circuit) may be constituted to control reading of data from the non-volatile memory 12-2 and recording of the data in the non-volatile memory 12-2. The CP 11-8 (or a communication processing circuit) may be constituted to process data obtained from the components of the processor 11 in a format appropriate for being transmitted to another electronic device through the communication circuit 16, or process data obtained from another electronic device through the communication circuit 16 in a format appropriate for processing the components of the processor 11. For example, the communication circuit 16 may include one or more communication circuits. The sensor interface 11-9 (or a sensing data processing circuit, a sensor hub) may be constituted to process data regarding the state of the electronic device 10 and/or the state of the surroundings of the electronic device 10 obtained through the sensor 17 in a format appropriate for the components of the processor 11.

According to an embodiment, the memory 12 may include one or more storage media (or one or more storage devices). For example, the memory 12 may include a memory assembly including one or more storage media. For example, the one or more storage media may include permanent memory (e.g., the non-volatile memory 12-2) such as a hard disc drive, flash memory, and read-only memory (ROM), semi-permanent memory (e.g., the volatile memory 12-1) such as random access memory (RAM), a storage (or a storage assembly) of any other suitable type, or any combination thereof. The memory 12 may include cache memory which is memory of one or more different types that is used for temporarily storing data for the functions or the features of the electronic device 10. As an unlimited example, the cache memory may be included inside the processor 11. The memory 12 may be fixedly embedded in the electronic device 10, or incorporated onto one or more suitable types of components (e.g.: a subscriber identity module (SIM) card and/or a secure digital (SD) card) that can be repeatedly inserted into the electronic device 10 and can be removed from the electronic device 10.

For example, the memory 12 may store one or more software applications such as an operating system (or a system) software application, a firmware software application, a driver software application, a plug-in (e.g., an add-in, an add-on, and/or an applet) software application, and/or any other suitable software applications. For example, the one or more software applications may include instructions that can be executed by the processor 11. For example, the memory 12 may store instructions that can be called by an application programming interface (API). For example, the memory 12 may store instructions within a library.

According to an embodiment, the communication circuit 16 may establish a direct (e.g.: wired) communication channel or a wireless communication channel between the electronic device 10 and an external electronic device (e.g.: another electronic device (not shown) or a server (not shown)), and support performance of communication through the established communication channel. The communication circuit 16 may include one or more communication processors that are operated independently from the processor 11 (e.g.: an application processor), and support direct (e.g.: wired) communication or wireless communication. According to an embodiment, the communication circuit 16 may include a wireless communication circuit 16-1 (e.g.: a cellular communication circuit, a near field wireless communication circuit, or a global navigation satellite system (GNSS) communication circuit) or a wired communication circuit 16-2 (e.g.: a local area network (LAN), or a power line communication circuit). A corresponding communication circuit among these communication circuits may communicate with the external electronic device (not shown) through a first network (e.g.: a near field communication network such as Bluetooth, wireless fidelity (Wi-Fi) direct, or infrared data association (IrDA)) or a second network (e.g.: a long distance communication network such as a legacy cellular network, a fifth generation (5G) network, a next generation communication network, the Internet, or a computer network (e.g.: a LAN or a wide area network (WAN)). These several kinds of communication circuits may be integrated as one component (e.g.: a single chip), or implemented as a plurality of components (e.g.: a plurality of chips) separate from one another. The wireless communication circuit 16-1 may identify or authenticate the electronic device 10 in a communication network such as the first network or the second network by using subscriber information (e.g.: an international mobile subscriber identity (IMSI)) stored in a subscriber identification module (not shown).

For example, the wireless communication circuit 16-1 may support the 5G network after the fourth generation (4G) network and a next generation communication technology, e.g., a new radio (NR) access technology. The NR access technology may support high speed transmission of high capacity data (enhanced mobile broadband (eMBB)), minimalization of terminal power and access of a plurality of terminals (massive machine type communications (mMTC)), or high reliability and low latency (ultra-reliable and low-latency communications (URLLC)). The wireless communication circuit 16-1 may support, for example, a high frequency bandwidth (e.g.: an millimeter wave (mmWave) bandwidth) for achievement of a high data transmission rate.

For example, the wireless communication circuit 16-1 may support various technologies for securing performance in a high frequency bandwidth, e.g., technologies such as beamforming, massive multiple-input and multiple-output (MIMO), full dimensional MIMO (FD-MIMO), an array antenna, analog beam-forming, or a large scale antenna. The wireless communication circuit 16-1 may support various requirements prescribed in the electronic device 10 and an external electronic device (e.g.: another electronic device or a network system (e.g.: a second network)). According to an embodiment, the wireless communication circuit 16-1 may support a peak data rate (e.g.: 20 gigabits per seconds (Gbps) or higher) for realizing eMBB, a loss coverage (e.g.: about 164 dB or lower) for realizing mMTC, or U-plane latency (e.g.: 0.5 ms or lower of each of a downlink (DL) and an uplink (UL), or 1 ms or lower of a round trip) for realizing URLLC.

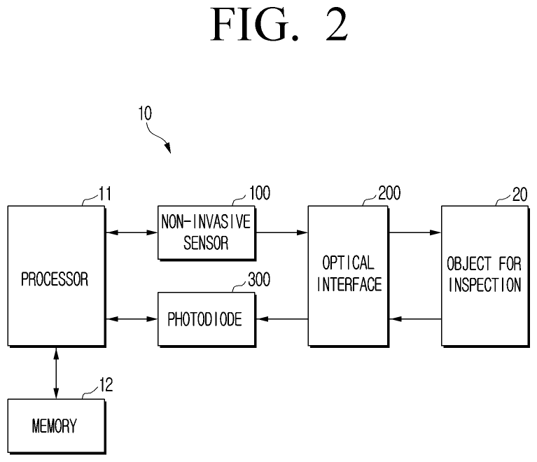

According to an embodiment, the sensor 17 may include, for example, an optical sensor (refer to 100 in FIG. 2) that can measure components by a non-invasive method for an object for inspection (referred to as an object for inspection 20 in FIG. 2 hereinafter, and for example, the object for inspection 20 may include the skin of a human body, blood vessels arranged inside the skin, and blood flowing through the blood vessels). The optical sensor 100 may emit lights of a defined wavelength band. The lights emitted from the optical sensor 100 may be incident on the object for inspection 20 through an optical interface (e.g.: an optical lens or optical film) (refer to 200 in FIG. 2). The lights incident on the object for inspection 20 may be absorbed and reflected inside the object for inspection 20. The sensor 17 may include a photodiode (refer to 300 in FIG. 2) that receives the lights reflected on the object for inspection 20. The lights reflected on the object for inspection 20 may be incident on the photodiode 300 through the optical interface 200. The photodiode 300 may convert an optical signal into an electric signal. The electric signal may be a biometric signal. The processor 11 may analyze the object for inspection based on data stored in advance in the memory 12, on the basis of the converted electric signal.

At least some of the above components may be connected with one another through communication methods among adjacent devices (e.g.: a bus, a general purpose input and output (GPIO), a serial peripheral interface (SPI), or a mobile industry processor interface (MIPI)), and exchange signals (e.g.: instructions or data) with one another.

According to an embodiment, instructions or data may be transmitted or received between the electronic device 10 and external electronic devices (not shown) through a server (not shown) connected to the second network. Each of the external electronic devices (not shown) may be a device of a type that is the same as or different from the electronic device 10. According to an embodiment, all or some of the operations executed in the electronic device 10 may be executed in one or more external electronic devices among the external electronic devices (not shown). For example, in case the electronic device 10 needs to perform a function or a service automatically, or in response to a request from a user or another device, the electronic device 10 may request one or more external electronic devices to perform at least a part of the function or the service instead of executing the function or the service by itself, or in addition to it. The one or more external electronic devices that received the request may execute at least a part of the requested function or service, or an additional function or service related to the request, and transmit the result of execution to the electronic device 10. The electronic device 10 may process the result as it is or additionally, and provide the result as at least a part of a response to the request. For this, a cloud computing technology, a distributive computing technology, a mobile edge computing (MEC) technology, or a client-server computing technology may be used, for example. The electronic device 10 may, for example, provide an ultra low-latency service by using distributed computing or mobile edge computing. The electronic device 10 may be applied to an intelligent service (e.g.: smart home, smart city, smart car, or healthcare) based on 5G communication technologies and IoT related technologies.

FIG. 2 is a block diagram illustrating an example including a component that may sense a biometric signal by a non-invasive method of an electronic device according to an embodiment of the disclosure.

Referring to FIG. 2, the electronic device 10 according to an embodiment may include a housing wherein at least a part thereof includes a light transmitting area (refer to 19-1 in FIG. 1), an optical sensor 100 that is arranged inside the housing 19-1 and can emit a light through the light transmitting area of the housing 19-1 and receive a light reflected on the object for inspection 20, an optical interface 200, and a photodiode 300. The optical sensor 100 may measure an object for inspection in a non-invasive way. For example, the electronic device 10 to which the optical sensor 100 is applied may apply an optical signal on the skin without a blood sampling process using a lancet, and analyze an electric signal that appears in response to the optical signal, and measure the components inside the blood. In this case, the electronic device 10 does not use a lancet for measuring the components of the object for inspection (e.g.: blood), and thus pain may not be caused to the testee, and the amount of the components (blood sugar) inside the skin can be measured more swiftly and correctly, and as the electronic device 10 is portable, there may be no restriction on a place for measurement.

The optical sensor 100 according to an embodiment may measure biomedical characteristics. For example, the optical sensor 100 may perform cancer detection, disease detection, blood sugar measurement, in vivo metabolic fingerprinting inspection and/or hyperspectral imaging. The optical sensor 100 may be applied in measuring an object for inspection by a non-invasive method. For example, an object for inspection may be components inside the blood (e.g.: blood sugar, protein, lactic acid, alcohol, glucose, hemoglobin, bilirubin, cholesterol, albumin, creatinine, and glycated hemoglobin) and bodily fluids (e.g.: saliva, sweat, and urine), microorganisms, enzymes, and cells. The optical sensor 100 according to an embodiment may also be applied to a petrochemical device. In this case, the optical sensor 100 may be applied in measuring the temperature, the pressure, and the concentration of chemical components in a petrochemical process.

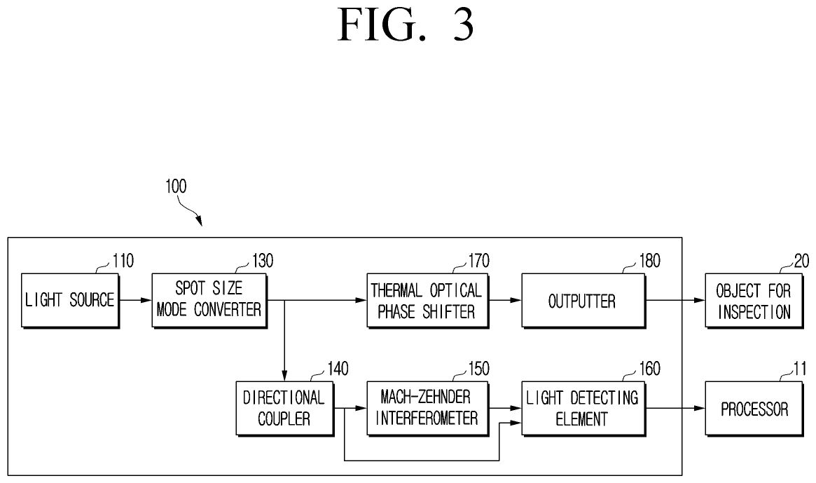

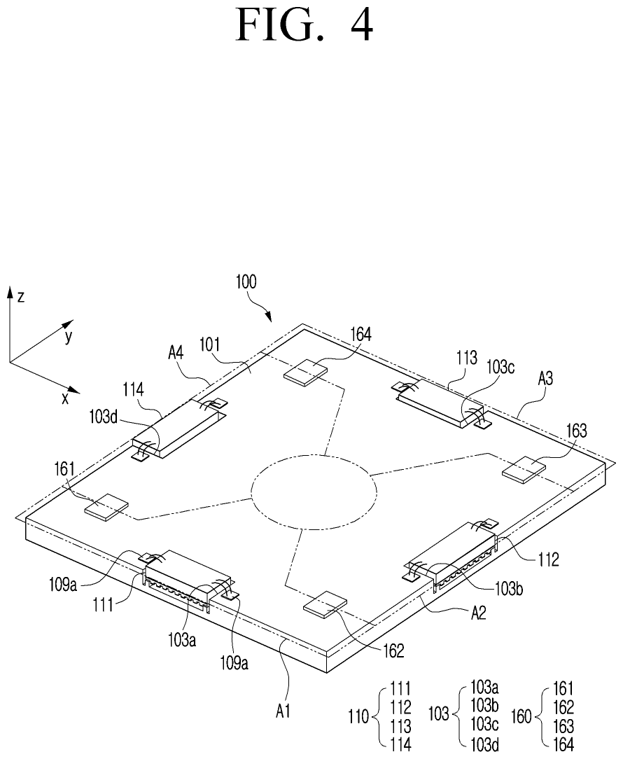

According to an embodiment, the optical sensor 100 may emit lights (e.g.: laser) having different wavelengths from a light source (e.g.: refer to 110 in FIG. 3) such that a defined wavelength band can be covered for measuring an object for inspection. For example, a wavelength band that can be covered by the optical sensor 100 may be, for example, about 2000 nanometer (nm)-2400 nm, about 1500 nm-1800 nm, or about 1000 nm-1400 nm. For example, the light source 110 may include a plurality of laser diodes (e.g.: refer to 111, 112, 113, and 114 in FIG. 4). Each of the plurality of laser diodes may emit lights of different wavelengths within a defined wavelength band, and thus the defined wavelength band can be covered while minimizing the number of the laser diodes included in the optical sensor 100. Accordingly, the optical sensor 100 can have a compact size, and the structure of a light source can be constituted to be simpler, and thus the manufacturing process can be simplified and/or the manufacturing cost can be reduced.

According to an embodiment, the optical sensor 100 can improve reduction of optical intensity and improve focusing efficiency by minimizing coupling loss that may occur when a light emitted from a light source is incident on a waveguide provided on a substrate (e.g.: refer to 101 in FIG. 4). The optical sensor 100 can improve measurement reliability by monitoring lights that are emitted as the internal temperature and/or the external temperature of the light source 110 is changed in real time when lights are emitted from the light source 110, and controlling the light output in case the strength of the lights is changed.

According to an embodiment, the optical interface 200 may introduce lights emitted from the optical sensor 100 into the object for inspection 20. The optical interface 200 may transmit a light emitted from a light source to the skin, and collect the light reflected or transmitted through the skin again. For example, the optical interface 200 can improve to reduce loss of lights by adjusting lights emitted from a light source to be incident on the skin appropriately. The optical interface 200 can improve the detection accuracy by preventing unnecessary reflection or scattering of lights on the surface of the skin.

For example, the optical interface 200 may include an optical lens, an optical diffuser, and/or anti-reflection film. In case the optical interface 200 includes an optical lens (e.g.: a convex lens or an aspherical lens), the optical interface 200 can intensify a measurement signal by concentrating lights on a narrow area of the skin. In case the optical interface 200 includes a light diffusing filter, the optical interface 200 may disperse lights evenly and make them incident on the surface of the skin by regular strength, and thus it may be advantageous for correcting structural irregularity of the skin. In case the optical interface 200 includes anti-reflection film, the optical interface 200 can improve a signal-to-noise ratio (SNR) by further minimizing interference of lights by reducing unnecessary reflection and improving the transmittance.

According to an embodiment, the photodiode 300 may receive lights that are reflected on the object for inspection 20 and pass through the optical interface 200 among lights incident on the object for inspection 20. The photodiode 300 may convert the received lights (e.g.: optical signals) into electric signals that can be processed at the processor 11. For example, the photodiode 300 may be a photodiode that is sensitive to a specific wavelength so as to be designed based on an absorbing property of a specific component (e.g.: glucose) of the object for inspection 20 (e.g.: blood). Also, the photodiode 300 may be a photodiode that has a low noise property such that it can have higher accuracy.

Hereinafter, the optical sensor 100 according to an embodiment will be explained with reference to the drawings.

FIG. 3 is a block diagram illustrating an optical sensor according to an embodiment of the disclosure.

FIG. 4 is a perspective view illustrating an optical sensor according to an embodiment of the disclosure.

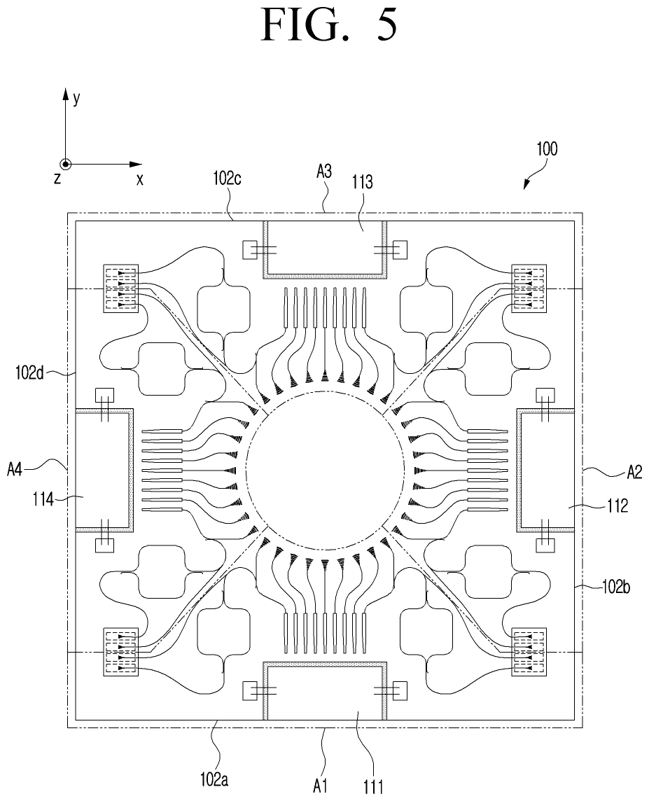

FIG. 5 is a plan view of an optical sensor, and is a diagram illustrating an example of partitioning the optical sensor 100 into first, second, third, and fourth areas according to an embodiment of the disclosure.

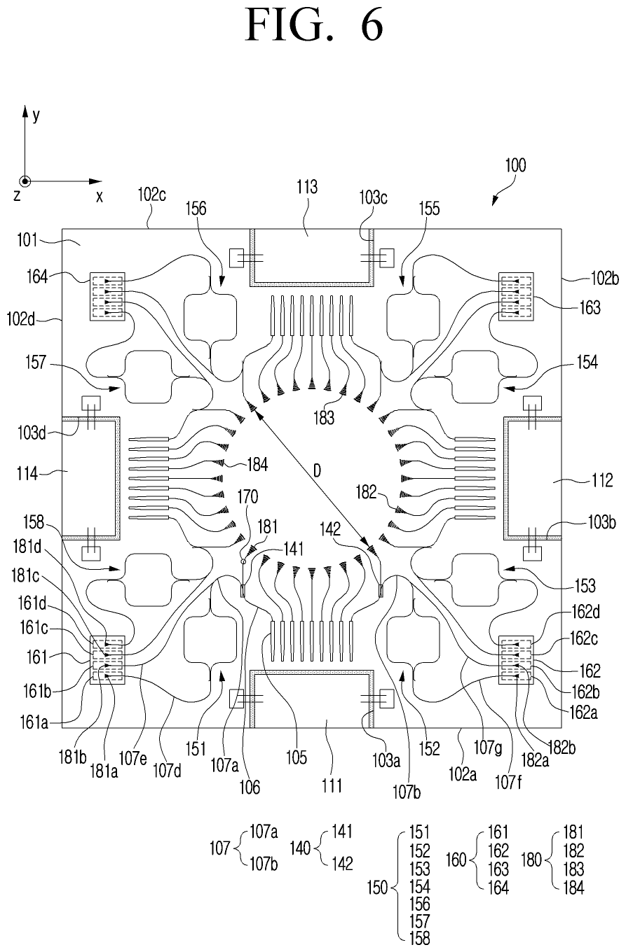

FIG. 6 is a plan view illustrating the optical sensor 100 according to an embodiment of the disclosure.

Referring to FIGS. 3, 4, 5, and 6, the optical sensor 100 according to an embodiment may be implemented through a silicon photonics technology. The optical sensor 100 may be a photonic integrated circuit that is constituted based on silicon, and generates, transmits, manipulates, and detects lights emitted from laser diodes.

According to an embodiment, the optical sensor 100 may emit lights covering a defined wavelength band (e.g.: about 2000 nm-2400 nm). For example, the optical sensor 100 may include a first area A1 that may emit lights of different wavelengths between about 2000 nm-2100 nm, a second area A2 that may emit lights of different wavelengths between about 2100 nm-2200 nm, a third area A3 that may emit lights of different wavelengths between about 2200 nm-2300 nm, and a fourth area A4 that may emit lights of different wavelengths between about 2300 nm-2400 nm. For example, the first area A1 and the third area A3 of the optical sensor 100 may be arranged to face each other, and the second area A2 and the fourth area A4 of the optical sensor 100 may be arranged to face each other. In this case, the second area A2 and the fourth area A4 of the optical sensor 100 may be arranged between the first area A1 and the third area A3 of the optical sensor 100.

According to an embodiment, the wavelength bands that can be covered by the optical sensor 100 are not limited to about 2000 nm-2400 nm. For example, the optical sensor 100 may cover wavelength bands of about 1500 nm-1800 nm or about 1000 nm-1400 nm. In this case, the light source 110 may be constituted to emit lights of different wavelengths in these wavelength bands.

According to an embodiment, the optical sensor 100 may include a plurality of light output structures 180 that emit lights emitted from the first area A1, the second area A2, the third area A3, and the fourth area A4 toward the object for inspection 20. For example, in consideration of the arrangement of the first area A1, the second area A2, the third area A3, and the fourth area A4 of the optical sensor 100, the plurality of light output structures 180 may be arranged in an approximately circular form to surround the area wherein the object for inspection is located. For example, the plurality of light output structures 180 arranged in a circular form may output lights toward the optical interface 200 (refer to FIG. 2) (e.g.: a lens) spaced apart from the top surface of the substrate 101 by a defined interval. The lights emitted from the plurality of light output structures 180 may be focused on one point of the object for inspection 20 by the optical interface 200. In this case, the center of the circular arrangement of the plurality of light output structures 180 and the center of the optical interface 200 may be arranged coaxially. Such a design of the optical sensor 100 can provide the length of the paths of lights transmitted from the first area A1, the second area A2, the third area A3, and the fourth area A4 of the optical sensor 100 to each of the plurality of light output structures 180 in an approximately identical level. Accordingly, light outputs emitted from the first area A1, the second area A2, the third area A3, and the fourth area A4 of the optical sensor 100 can be maintained to be mostly homogenous.

For example, the plurality of light output structures 180 may include a plurality of first light output structures 181 that are connected to structures guiding lights emitted from a first laser diode 111 of the first area A1 (e.g., a plurality of first waveguides 105 and a plurality of first lines 107a connected to the plurality of first waveguides 105). Also, the plurality of light output structures 180 may include a plurality of second light output structures 182, a plurality of third light output structures 183, and a plurality of fourth light output structures 184 that are respectively connected to structures guiding lights emitted from a second laser diode 112 of the second area A2, structures guiding lights emitted from a third laser diode 113 of the third area A3, and structures guiding lights emitted from a fourth laser diode 114 of the fourth area A4. For example, the plurality of light output structures 180 may consist of grating couplers that can respectively emit lights toward the top surface of the substrate 101 approximately vertically.

According to an embodiment, the first area A1 of the optical sensor 100 may include a substrate 101, a light source 110, a spot size mode converter 130, a directional coupler 140, a Mach-Zehnder interferometer (MZI) 150, a light detecting element 160, a thermal optical phase shifter 170, and a plurality of light output structures 180. For example, the directional coupler 140 may include a first directional coupler 141 and a second directional coupler 142 corresponding to one laser diode.

According to an embodiment, the first area A1, the second area A2, the third area A3, and the fourth area A4 of the optical sensor 100 may share the substrate 101 which is a single component. The first area A1, the second area A2, the third area A3, and the fourth area A4 of the optical sensor 100 may share adjacent areas and two light detecting elements with one another. For example, the first area A1 of the optical sensor 100 may share a first light detecting element 161 with the fourth area A4, and share a second light detecting element 162 with the second area A2. For example, each of the second area A2, the third area A3, and the fourth area A4 of the optical sensor 100 may include components that are substantially identical to the components included in the first area A1.

According to an embodiment, the substrate 101 may consist of a quadrangle having four sides. However, the substrate 101 is not limited to a quadrangle, and may have various shapes (e.g.: a shape which is symmetrical in the left-right direction and/or the up-down direction or a shape which is asymmetrical in the left-right direction and/or the up-down direction) in consideration of the shape inside the electronic device 10.

According to an embodiment, the substrate 101 may include silicon or silicon nitride (Si₃N4). For example, silicon nitride may include characteristics of having relatively low light loss, and operating in various wavelength ranges.

According to an embodiment, on the substrate 101, an accommodating groove 103 to which the light source 110 can be coupled may be provided. For example, the accommodating groove 103 may include a first accommodating groove 103a, a second accommodating groove 103b, a third accommodating groove 103c, and a fourth accommodating groove 103d respectively corresponding to a first side 102a, a second side 102b, a third side 102c, and a fourth side 102d of the substrate 101.

According to an embodiment, the light source 110 may include a first laser diode 111, a second laser diode 112, a third laser diode 113, and a fourth laser diode 114. For example, each of the first laser diode 111, the second laser diode 112, the third laser diode 113, and the fourth laser diode 114 may emit lights of different wavelengths. To each of the first accommodating groove 103a, the second accommodating groove 103b, the third accommodating groove 103c, and the fourth accommodating groove 103d of the substrate 101, the first laser diode 111, the second laser diode 112, the third laser diode 113, and the fourth laser diode 114 may be coupled. For example, lights emitted from the light source 110 may be used in measuring the components of the object for inspection 20. Some lights among the lights emitted from the light source 110 may be used in measuring changes of wavelengths by the Mach-Zehnder interferometer 150 in real time, and monitoring noises of optical signals by the light detecting element 160 in real time. For example, the light detecting element 160 may include a first light detecting element 161 that detects lights emitted from the first laser diode 111, a second light detecting element 162 that detects lights emitted from the second laser diode 112, a third light detecting element 163 that detects lights emitted from the third laser diode 113, and a fourth light detecting element 164 that detects lights emitted from the fourth laser diode 114.

According to an embodiment, the substrate 101 may include a plurality of waveguides 105 included in a path that transports a light emitted from the light source 110 to the light detecting element 160. For example, the plurality of waveguides 105 may correspond to each of the first, second, third, and fourth laser diodes 111, 112, 113, 114 such that they can transmit a plurality of lights emitted from each of the first, second, third, and fourth laser diodes 111, 112, 113, 114. For example, the plurality of waveguides 105 may respectively be arranged to be substantially parallel by a defined interval along the longitudinal direction of the corresponding first, second, third, and fourth laser diodes 111, 112, 113, 114 on the same plane (e.g.: the x-y plane in FIG. 6). For example, each of the plurality of waveguides 105 may include a first end into which lights enter and a second end which is arranged on the opposite side of the first end, and through which lights go out.

For example, the first laser diode 111 may emit nine lights of different wavelengths. In this case, the plurality of waveguides 105 may include nine waveguides so as to correspond to points wherein each of the nine lights is emitted. Like this, the plurality of waveguides 105 may be arranged to correspond to the number of lights emitted from the first laser diode 111. For example, the plurality of waveguides 105 may be arranged to correspond to the number of lights emitted from the first laser diode 111. For example, points wherein lights of the first laser diode 111 are emitted may be arranged by a defined interval along the longitudinal direction of the first laser diode 111 (e.g.: the x axis direction in FIG. 6). For example, in case lights emitted from the first laser diode 111 cover a wavelength band of about 2000 nm-2100 nm, the lights may have wavelengths that gradually increase by a specific wavelength interval as it is more to the right side of the first laser diode 111 from the left side. For example, a light emitted from the most adjacent point to the left side of the first laser diode 111 may have a minimum wavelength (e.g.: about 2000 nm) or a wavelength adjacent to the minimum wavelength, and a light emitted from the most adjacent point to the right side of the first laser diode 111 may have a maximum wavelength (e.g.: about 2100 nm) or a wavelength adjacent to the maximum wavelength.

According to an embodiment, the number of lights emitted from the first laser diode 111 and the plurality of waveguides 105 may not be limited to nine, respectively. For example, the number of lights emitted from the first laser diode 111 and the plurality of waveguides 105 may include a defined number that can cover a defined wavelength wherein an object for inspection can be measured (e.g.: the number of lights emitted from a light source is about 36 or more).

According to an embodiment, the substrate 101 may include a plurality of first optical lines 106 that guide lights transmitted along the plurality of guides 105 to the light output structures 180. Each of the plurality of first optical lines 106 may include a first end into which lights transmitted from the waveguides 105 enter and a second end which is arranged on the opposite side of the first end, and through which lights go out. In each of the plurality of first optical lines 106, the first end of the first optical line 106 may be connected to the second end of the waveguide 105, and the second end of the first optical line 106 may be connected to the light output structures 180. For example, lights emitted from the light source 110 may be transmitted along the plurality of waveguides 105, the plurality of first optical lines 106, and the plurality of light output structures 180, and may go through the optical interface 200 (refer to FIG. 2), and may be irradiated on the object for inspection 20.

According to an embodiment, the substrate 101 may include second optical lines 107 that are branched from some of the first optical lines 106 among the plurality of first optical lines 106. For example, the second optical lines 107 may be respectively branched from the first optical line wherein the shortest wavelength is transmitted (e.g.: the first optical line that is the most adjacent to the left side of the first laser diode 111 in FIG. 6), and the first optical line wherein the longest wavelength is transmitted (e.g.: the first optical line that is the most adjacent to the right side of the first laser diode 111 in FIG. 6) among the plurality of first optical lines 106. In this case, the number of the second optical lines 107a, 107b corresponding to the first laser diode 111 may be two. For example, lights transmitted through the two second optical lines 107a, and 107b may be respectively guided to a first Mach-Zehnder interferometer 151 and a second Mach-Zehnder interferometer 152 respectively corresponding to the two second optical lines 107a, and 107b. The lights that passed through the first and second Mach-Zehnder interferometers 151, and 152 may be respectively incident on the corresponding first light detecting element 161 and the corresponding second light detecting element 162. The first and second light detecting elements 161, and 162 may respectively convert a received optical signal into an electric signal.

According to an embodiment, the substrate 101 may include a third optical line 107d that is connected to a light outlet of the first Mach-Zehnder interferometer 151, and a fourth optical line 107e that is branched from the second optical line 107a. For example, the third optical line 107d may be connected to a first grating coupler 181a. A light that passed through the first Mach-Zehnder interferometer 151 may be guided to the first grating coupler 181a through the third optical line 107d. For example, the fourth optical line 107e may be connected to a second grating coupler 181b. A light that is transmitted along the fourth optical line 107e may be guided to the second grating coupler 181b.

According to an embodiment, the substrate 101 may include a fifth optical line 107f that is connected to a light outlet of the second Mach-Zehnder interferometer 152, and a sixth optical line 107g that is branched from the second optical line 107b. For example, the fifth optical line 107f may be connected to a fifth grating coupler 182a. A light that passed through the second Mach-Zehnder interferometer 152 may be guided to the fifth grating coupler 182a through the fifth optical line 107f. For example, the sixth optical line 107g may be connected to a sixth grating coupler 182b. A light that is transmitted along the sixth optical line 107g may be guided to the sixth grating coupler 182b.

For example, if it is determined that light outputs were reduced more than defined reference light outputs based on an electric signal received through the first and second light detecting elements 161, 162, the processor 11 may control the light output by increasing the amount of currents. After the amount of currents increased, the wavelength of an optical signal may be changed in the direction of a long wavelength by a ratio of about 0.09-0.1 nm/mA. Such a change of a wavelength may be measured through the first and second Mach-Zehnder interferometers 151, and 152. The processor 11 may receive a measurement signal received from the first and second Mach-Zehnder interferometers 151, and 152, and receive a feedback about the increased amount of light outputs at the light output structures 180 based on this, and in case the amount did not reach the defined light outputs, the processor 11 may perform control to additionally increase the amount of currents. As described above, the first and second Mach-Zehnder interferometers 151, and 152 of the optical sensor 100 may be used as feedback circuitry.

For example, the first Mach-Zehnder interferometer 151 may be connected to the first optical line 106 that transmits the minimum wavelength in the wavelength band emitted from the first laser diode 111 (e.g.: the first optical line corresponding to the leftmost side of the first laser diode 111 in FIG. 6), and the second Mach-Zehnder interferometer 152 may be connected to the first optical line 106 that transmits the maximum wavelength in the wavelength band emitted from the first laser diode 111 (e.g.: the first optical line corresponding to the rightmost side of the first laser diode 111 in FIG. 6).

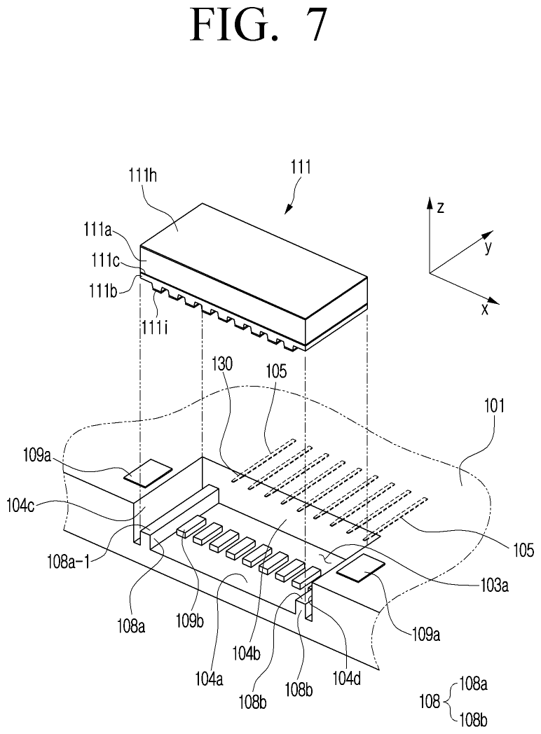

FIG. 7 is a diagram illustrating an example wherein a light source is coupled to a substrate of an optical sensor according to an embodiment of the disclosure.

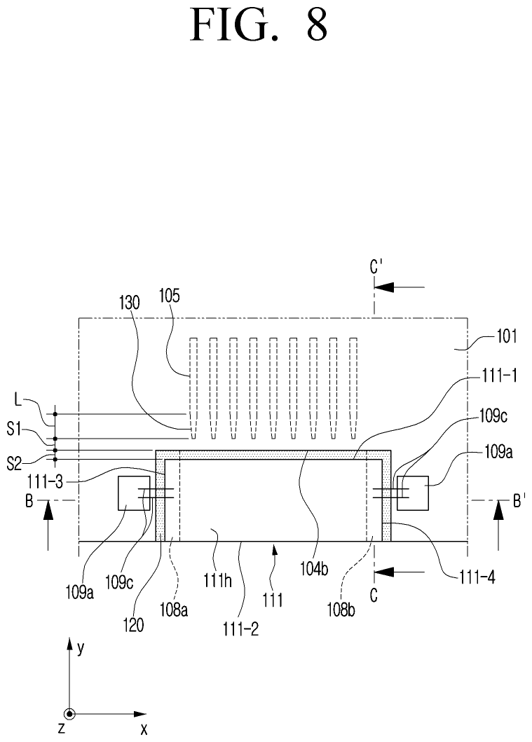

FIG. 8 is a plan view illustrating an example wherein a light source is coupled to a substrate of an optical sensor according to an embodiment of the disclosure.

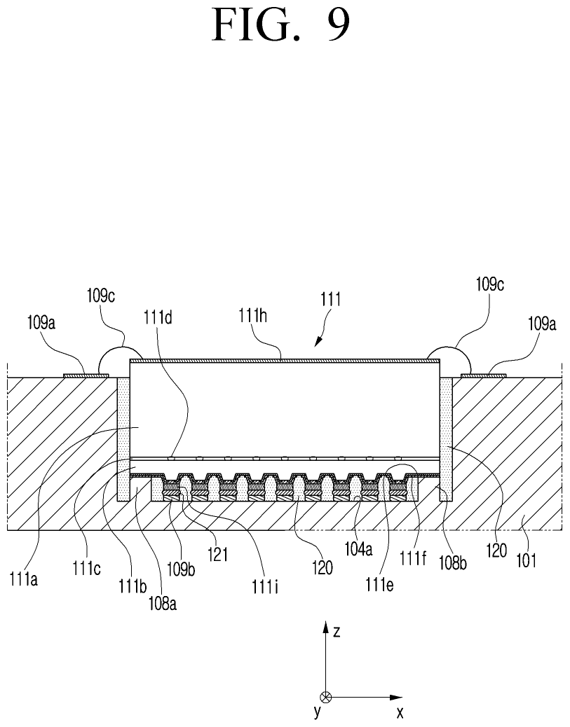

FIG. 9 is a cross-sectional view illustrated along the B-B′ line displayed in FIG. 8 according to an embodiment of the disclosure.

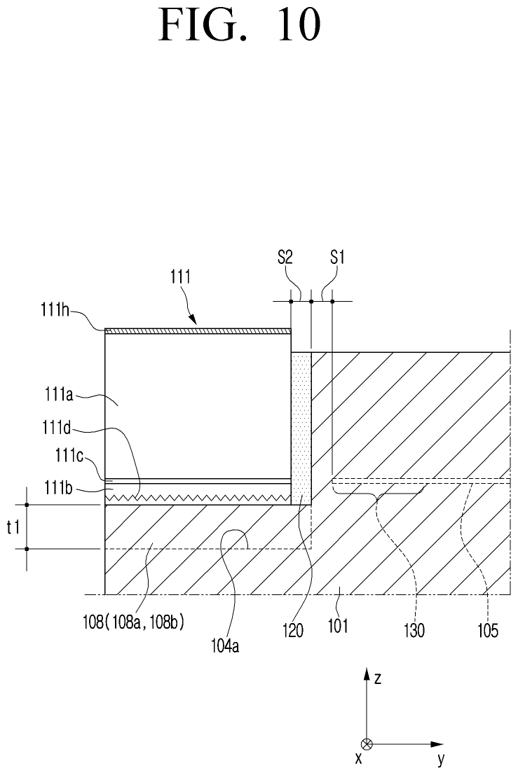

FIG. 10 is a cross-sectional view illustrated along the C-C′ line displayed in FIG. 8 according to an embodiment of the disclosure.

Referring to FIGS. 7, 8, 9, and 10, the substrate 101 according to an embodiment may include a support 108 that can support the bottom surface of the first laser diode 111 on the bottom surface 104a of the first accommodating groove 103a. For example, the support 108 may include a first stopper 108a and a second stopper 108b that respectively support both sides of the bottom surface of the first laser diode 111.

According to an embodiment, on the front surface 111-1 and the rear surface 111-2 of the first laser diode 111, reflective coating may respectively be formed for controlling the performance and adjusting the output property. For example, on the front surface 111-1 of the first laser diode 111 from which lights are emitted, anti-reflection (AR) coating (not shown) may be formed for minimizing light reflection, and on the rear surface 111-2 of the first laser diode 111, high-reflection (HR) coating (not shown) may be formed for maximizing light reflection.

According to an embodiment, on the top surface of the first laser diode 111 (e.g.: the top surface of the first semiconductor layer 111a), a first electrode 111h may be arranged. For example, the first electrode 111h may be electrically connected to a plurality of first pads 109a arranged on the top surface of the substrate 101 through a plurality of wires 109c. The plurality of first pads 109a may be located to be adjacent to the surroundings of the accommodating groove 103.

According to an embodiment, in case the first laser diode 111 is rested on the top surface of the support 108, it may be aligned with the plurality of waveguides 105 to which points 111d wherein lights are emitted correspond on the front surface 111-1 of the first laser diode 111 by the support 108. For example, the support 108 may include a first stopper 108a and a second stopper 108b that respectively support the both sides of the bottom surface of the first laser diode 111. In this case, the both sides of the bottom surface of the first laser diode 111 may be respectively rested on the top surface 108a-1 of the first stopper 108a and the top surface 108b-1 of the second stopper 108b. The points 111d wherein lights are emitted on the front surface 111-1 of the first laser diode 111 may be located on an active layer 111c of the first laser diode 111. Like this, the support 108 may be constituted to have thickness t1 at which the active layer 111c of the first laser diode 111 can be aligned with the plurality of waveguides 105 (e.g.: the height from the bottom surface 104a of the first accommodating groove 103a to the top surface of the support 108 along the z axis direction in FIG. 7). For example, the center line of the active layer 111c of the first laser diode 111 (e.g.: a virtual center line parallel to the y axis in FIG. 10) and the center line of the plurality of waveguides 105 (e.g.: a virtual center line parallel to the y axis in FIG. 10) may be located on the same x-y plane. For example, the thickness of the first stopper 108a and the thickness of the second stopper 108b may have substantially the same thickness t1. Like this, as the active layer 111c of the first laser diode 111 and the plurality of waveguides 105 are aligned, coupling loss of lights that are emitted from the active layer 111c of the first laser diode 111 and are incident on the plurality of waveguides 105 can be minimized, and optical attenuation can thereby be improved.

According to an embodiment, there may be elements that should be additionally considered for alignment of the active layer 111c of the first laser diode 111 and the plurality of waveguides 105. For example, the elements may include the thickness of a second semiconductor layer 111b (e.g.: a p type semiconductor layer) of the first laser diode 111, the thickness of a passivation layer 111e covering the second semiconductor layer 111b, the thickness of a conductive metal layer 111f covering the passivation layer 111e, the thickness of a second electrode 111i electrically connected to the second semiconductor layer 111b through the conductive metal layer 111f, the thickness of a second pad 109b that may be arranged on the bottom surface 104a of the first accommodating groove 103a of the substrate 101, and the thickness of a solder 121 for electrically connecting the second electrode 111i and the second pad 109b.

According to an embodiment, the spot size mode converter 130 can reduce or improve loss of optical signals between the first laser diode 111 and the plurality of waveguides 105. On each of the plurality of waveguides 105, the spot size mode converter 130 may be provided on the first end of the waveguide 105 into which lights enter. The first end of the spot size mode converter 130 may be constituted by an edge coupling method of maintaining a first distance S1 from the first surface 104b of the first accommodating groove 103a on which lights emitted from the first laser diode 111 are incident.

According to an embodiment, the spot size mode converter 130 may have an inversed taper shape wherein the first end of the spot size mode converter 130 corresponding to the first surface 104b of the first accommodating groove 103a is formed to be narrower than the second end of the spot size mode converter 130 connected with the waveguides 105. The spot size mode converter 130 may gradually reduce a mode size of lights that enter the spot size mode converter 130 to convert the size to coincide with the waveguide mode, and can thereby minimize energy loss of lights, and improve optical coupling with the waveguides 105.

According to an embodiment, the spot size mode converter 130 may have a defined length L (e.g.: the passivation length along the y axis direction in FIG. 8). For example, if the length of the spot size mode converter 130 is shorter than the defined length L, it is difficult to appropriately modify the mode size of lights, and thus lights may be coupled with the waveguides 105 incompletely, and excessive coupling loss may occur.

According to an embodiment, a space having the width of a second interval S2 may be provided between the first laser diode 111 and the first accommodating groove 103a. For example, each of the front surface 111-1, the left side surface 111-3, and the right side surface 111-4 of the first laser diode 111 may be spaced apart from the first surface 104b, the second surface 104c, and the third surface 104d of the first accommodating groove 103a by the second interval S2.

According to an embodiment, epoxy resin 120 may be filled in the space provided between the first laser diode 111 and the first accommodating groove 103a. The epoxy resin 120 may be filled between the bottom surface 104a of the first accommodating groove 103a of the substrate 101 and the bottom surface of the first laser diode 111.

According to an embodiment, the epoxy resin 120 may create an environment wherein a refractive index gradually changes. Accordingly, reflection of lights emitted from the first laser diode 111 on the first surface 104b of the first accommodating groove 103a and returning to the front surface 111-1 of the first laser diode 111 can be reduced or improved.

According to an embodiment, the epoxy resin 120 may buffer thermal expansion according to the internal or external temperature that increases during driving of the first laser diode 111. By improving change of the position of the first laser diode 111 within the first accommodating groove 103a of the substrate 101 through the epoxy resin 120, physical stability can be maintained. Accordingly, the alignment state between the active layer 111c of the first laser diode 111 and the plurality of waveguides 105 of the substrate 101 can be maintained.

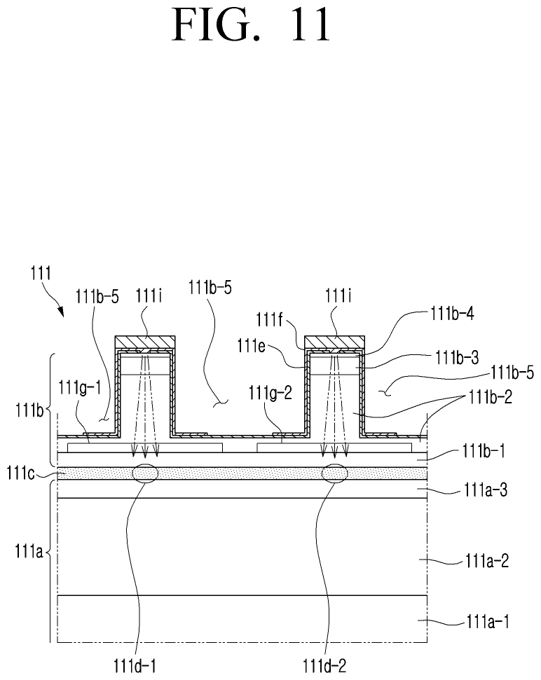

FIG. 11 is a diagram that enlarged a part of a light source according to an embodiment of the disclosure.

Referring to FIG. 11, according to an embodiment, the first laser diode 111 may be a single chip that emits lights of different wavelength bands by a defined interval. For example, the first laser diode 111 may include a first semiconductor layer (e.g.: an n type semiconductor layer) 111a, a second semiconductor layer (e.g.: a p type semiconductor layer) 111b, and an active layer 111c between the first semiconductor layer 111a and the second semiconductor layer 111b.

According to an embodiment, the first semiconductor layer 111a may include an n type substrate layer 111a-1, an n type cladding layer 111a-2 on the n type substrate layer 111a-1, and an n type waveguide layer 111a-3 located on the n type cladding layer 111a-2. The n type cladding layer 111a-2 may stabilize a current path, and improve leakage of currents from the active layer 111c to the surroundings. The n type waveguide layer 111a-3 may have a similar refractive index to the active layer 111c, and guide lights to proceed in a defined direction.

According to an embodiment, the second semiconductor layer 111b may include a p type waveguide layer 111b-1, a p type cladding layer 111b-2 located on the p type waveguide layer 111b-1, a p type buried layer 111b-3 located on the p type cladding layer 111b-2, and a p type contact layer 111b-4 located on the p type buried layer 111b-3. The p type waveguide layer 111b-1 may constitute a symmetrical structure with the n type waveguide layer 111a-3, and may minimize loss of lights and guide lights to proceed on a defined path. The p type cladding layer 111b-2 may provide a difference in a refractive index for light guiding together with the n type cladding layer 111a-2, and may thereby improve leakage of lights from the active layer 111c. The p type buried layer 111b-3 may improve current injection efficiency, and improve oscillation stability by diffusing lights. The p type contact layer 111b-4 may be electrically connected to the second pad 109b of the substrate 101 through the conductive metal layer 111f and the second electrode 111i, and provide electric contact for power supply to the first laser diode 111, and may thereby make currents injected into the active layer 111c smoothly.

According to an embodiment, the p type cladding layer 111b-2 may be constituted so as to have doping concentration that becomes gradually lower as it is closer to an adjacent part to the p type waveguide layer 111b-1 from an approximately center part for making flow of a charge carrier smooth and reducing optical loss. Accordingly, the p type cladding layer 111b-2 can improve distribution of electric fields around the active layer 111c, and can optimize or improve optical and electrical performances.

According to an embodiment, the active layer 111c is a structure that emits lights as electrons and holes are coupled by injection of currents, and may have a high refractive index. The active layer 111c of the first laser diode 111 may be aligned with the plurality of waveguides 105 by the support 108. For example, when growing the p type cladding layer 111b-2, the thickness of the p type cladding layer 111b-2 may be adjusted such that the active layer 111c can be constituted as the height that can be aligned with the plurality of waveguides 105.

According to an embodiment, the active layer 111c may emit lights of different wavelengths. On the active layer 111c, points 111d-1, and 111d-2 wherein lights are respectively emitted may be provided in locations that approximately correspond to a plurality of second pads 109b. The points 111d-1, and 111d-2 wherein lights are emitted may be set by a plurality of trenches 111b-5 that are formed on the second semiconductor layer 111b by a defined interval by an etching process. In this case, currents propagated through the plurality of second pads 109b may be concentrated on specific areas of the active layer 111c. When currents are concentrated on specific areas (e.g.: the points 111d-1, and 111d-2 wherein lights are emitted) of the active layer 111c, areas wherein oscillation occurs on the active layer 111c become narrow, and the light-emitting efficiency of the first laser diode 111 can thereby be improved.

According to an embodiment, on the inside of the p type cladding layer 111b-2, lattice structures 111g-1, and 111g-2 that can selectively amplify lights only in a specific wavelength may be provided in areas corresponding to each light-emitting points 111d-1, and 111d-2. Accordingly, from each light-emitting points 111d-1, and 111d-2, lights of different wavelengths may be emitted. In FIG. 11, two light-emitting points 111d-1, and 111d-2 and two lattice structures 111g-1, and 111g-2 respectively corresponding thereto were illustrated in the first laser diode 111, but the disclosure is not limited thereto. For example, the first laser diode 111 may have three or more light-emitting points and three or more lattice structures respectively corresponding thereto. Accordingly, in case the first laser diode 111 was constituted so as to emit lights covering the wavelength band of about 2000 nm-2100 nm, lights may have different wavelengths included in the wavelength band of about 2000 nm-2100 nm.

According to an embodiment, the second laser diode 112, the third laser diode 113, and the fourth laser diode 114 may be constituted to be substantially identical to the first laser diode 111. In this case, in case the second laser diode 112 was constituted so as to emit lights covering the wavelength band of about 2100 nm 2200 nm, lights may have different wavelengths included in the wavelength band of about 2100 nm-2200 nm. In case the third laser diode 113 was constituted so as to emit lights covering the wavelength band of about 2200 nm-2300 nm, lights may have different wavelengths included in the wavelength band of about 2200 nm-2300 nm. In case the fourth laser diode 114 was constituted so as to emit lights covering the wavelength band of about 2300 nm-2400 nm, lights may have different wavelengths included in the wavelength band of about 2300 nm-2400 nm.

According to an embodiment, in case the active layer 111c includes AlGaAsSb/GaSb 3-5 group substances, it may emit lights of a wavelength band of about 2000 nm-2400 nm. In case the active layer 111c includes InGaAs/InP 3-5 group substances, it may emit lights of a wavelength band of about 1500 nm-1900 nm. In case the active layer 111c includes InxGayAlzAs/GaAs 3-5 group substances, it may emit lights of a wavelength band of about 1000 nm-1400 nm.

According to an embodiment, the first laser diode 111 may include distributed feedback laser (DFB). However, the first laser diode 111 is not limited to DFB, and may include distributed bragg reflector laser (DBR), a fabry-perot laser diode (FP-LD), or tunable laser. The first laser diode 111 may also include a reflective semiconductor optical amplifier (RSOA) and external distributed bragg reflector laser (DBR) together.

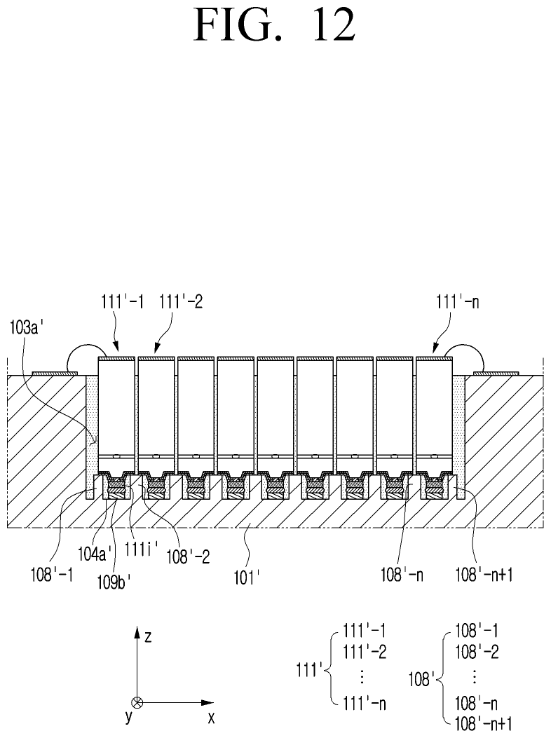

FIG. 12 is a diagram illustrating an example wherein a light source is coupled to a substrate according to an embodiment of the disclosure.

Referring to FIG. 12, the first laser diode 111′ coupled to the first accommodating groove 103a′ of the substrate 101′ is not limited to a single chip that emits lights of different wavelengths, and may consist of a plurality of first laser diodes 111′-1, 111′-2, . . . , and 111′-n. For example, the plurality of first laser diodes 111′-1, 111′-2, . . . , and 111′-n may respectively emit one light. In this case, lights emitted from each of the plurality of first laser diodes 111′-1, 111′-2, . . . , and 111′-n may have different wavelengths included in a defined wavelength band (e.g.: about 2000 nm-2100 nm).

According to an embodiment, the plurality of first laser diodes 111′-1, 111′-2, . . . , and 111′-n may be supported by the support 108′ protruding from the bottom surface 104a′ of the first accommodating groove 103a′ by a defined height. The support 108′ may include a plurality of stoppers 108′-1, 108′-2, . . . , 108′-n, and 108′-n+1.

According to an embodiment, in the single first laser diode 111′-1, the bottom surface of the first laser diode 111′-1 may be rested on the top surfaces of the two stoppers 108′-1, and 108′-2. The number of the plurality of stoppers 108′-1, 108′-2, . . . , 108′-n, 108′-n+1 may be one more than the number of the plurality of first laser diodes 111′-1, 111′-2, . . . , and 111′-n. The plurality of stoppers 108′-1, 108′-2, . . . , 108′-n, and 108′-n+1 may be constituted to have substantially the same length.

According to an embodiment, the second pad 109b′ corresponding to the second electrode 111i′ of the single first laser diode 111′-1 may be arranged between the two stoppers 108′-1, 108′-2. The second pads respectively corresponding to the second electrodes of the remaining plurality of first laser diodes 111′-2, . . . , and 111′-n may also be located between a pair of stoppers.

According to an embodiment, the second laser diode (refer to 112 in FIG. 6), the third laser diode (refer to 113 in FIG. 6), and the fourth laser diode (refer to 114 in FIG. 6) respectively coupled to the second accommodating groove (refer to 103b in FIG. 6), the third accommodating groove (refer to 103c in FIG. 6), and the fourth accommodating groove (refer to 103d in FIG. 6) of the substrate 101′ may also respectively include a plurality of laser diodes like the first laser diode 111′.

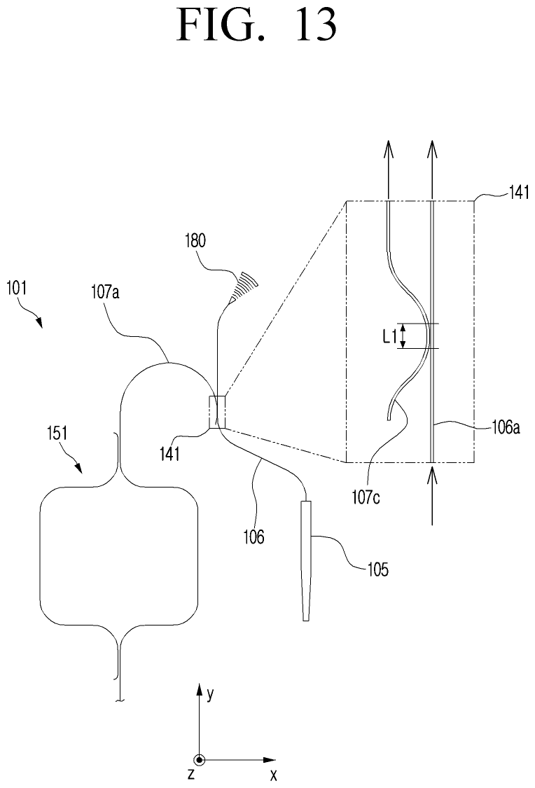

FIG. 13 is a diagram illustrating components formed on a substrate of the optical sensor according to an embodiment of the disclosure.

Referring to FIG. 13, according to an embodiment, the substrate 101 may include a first directional coupler 141 that is arranged on the first optical line 106 guiding lights transmitted along the waveguide 105 to the light output structures 180, and can distribute some of the lights that pass through the first optical line 106 to the first Mach-Zehnder interferometer 151. For example, the first directional coupler 141 may branch some light quantity (e.g.: about 5%, 10%, or 20%) from the entire light quantity of lights of a defined wavelength (e.g.: a minimum wavelength of a wavelength band of about 2000-2100 nm) transmitted along the first optical line 106 and transmit it to the first Mach-Zehnder interferometer 151 for monitoring the light intensity and the wavelength of the first laser diode 111. The first directional coupler 141 may include a part 106a of the first optical line 106 and a part 107c of the second optical line 107a that is arranged to be adjacent to the part 106a of the first optical line 106.

According to an embodiment, the first directional coupler 141 may be constituted to have a minimal coupling length and a cross-over length L1. Here, the minimal coupling length is the shortest length that enables an optical signal to be coupled sufficiently, and may be the length on a point wherein inter-coupling of the first optical line 106 and the second optical line 107a starts. If the minimal coupling length is too short, coupling becomes incomplete, and thus the quality of an output signal may deteriorate, and if it is too long, unnecessary loss may be generated. The cross-over length L1 is the length on a point wherein the first optical line 106 and the second optical line 107a start to independently operate without influencing each other, and it may be the length corresponding to a section consisting of a curve form that is convexly formed from a part 107c of the second optical line 107a toward a part 106a of the first optical line 106 in FIG. 13.

According to an embodiment, the first directional coupler 141 may include a section wherein a part 107c of the second optical line 107a is bended in an approximately S shape as in FIG. 13, such that it can have an appropriate minimal coupling length and an appropriate cross-over length. For example, the length of the section bended in an S shape may be about 40 μm. In this case, the light quantity that is distributed by the first directional coupler 141 and is transmitted along the first optical line 106 may be about 89.36%, and the distributed light quantity transmitted along the second optical line 107a may be about 8.96%. Lights transmitted along the second optical line 107a may be used in measuring a wavelength through the first Mach-Zehnder interferometer 151 and measuring the light intensity through the light detecting elements 161.

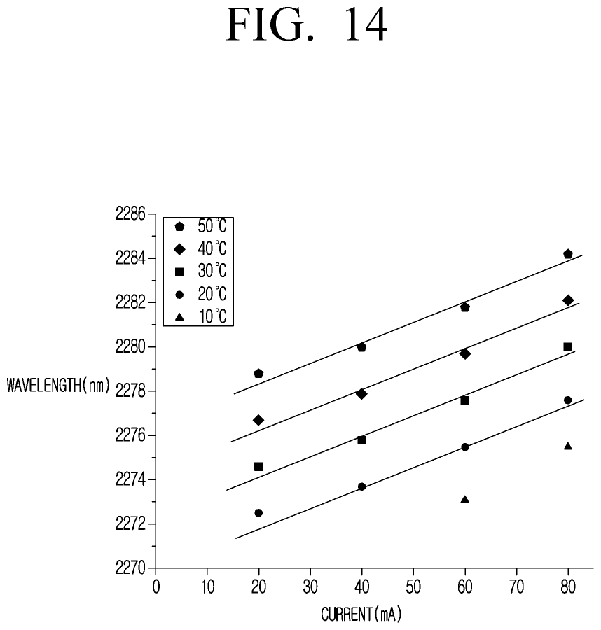

FIG. 14 is a graph illustrating an example wherein a wavelength of a light source changes according to a temperature and a current amount according to an embodiment of the disclosure. In FIG. 14, the x axis indicates a current amount (mA) applied to the first laser diode 111, and the y axis indicates some bands of a wavelength (nm) that the light source has.

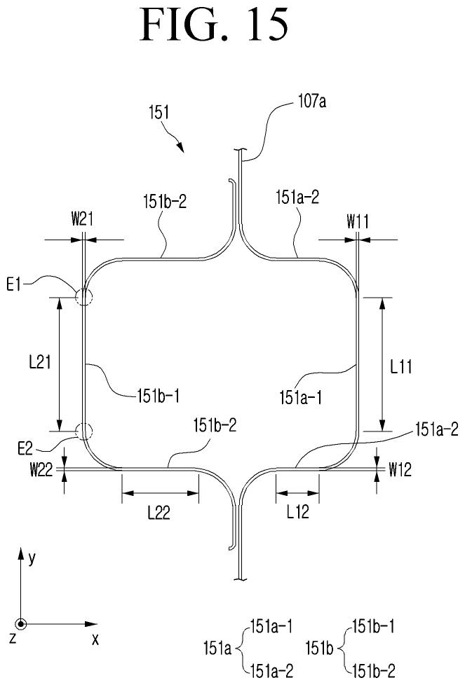

Referring to FIG. 14, the wavelength of the first laser diode 111 may change according to the external temperature and/or the internal temperature and an injected current amount. Referring to FIG. 15, in case a defined current amount (e.g.: about 40 mA) is injected into the first laser diode 111, if the temperature is about 20° C., the wavelength may be changed to about 2273 nm, and if the temperature is about 30° C., the wavelength may be changed to about 2275 nm, and if the temperature is about 40° C., the wavelength may be changed to about 2278 nm, and if the temperature is about 50° C., the wavelength may be changed to about 2280 nm. Like this, as the external temperature and/or the internal temperature increase, the light intensity of the first laser diode 111 may be reduced as its wavelength changes to a direction of a long wavelength.

FIG. 15 is a diagram illustrating the Mach-Zehnder interferometer formed on a substrate of an optical sensor according to an embodiment of the disclosure.

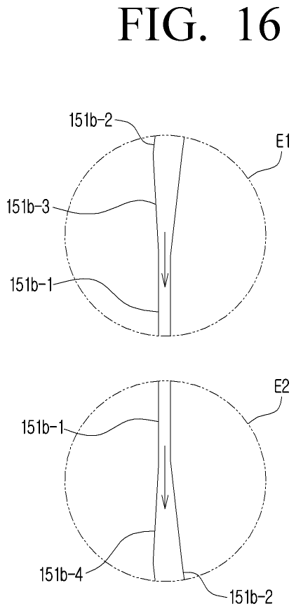

FIG. 16 is a diagram illustrating the E1 and E2 parts displayed in FIG. 15 which are parts of the Mach-Zehnder interferometer formed on a substrate of an optical sensor according to an embodiment of the disclosure.

Referring to FIG. 15, the first Mach-Zehnder interferometer 151 according to an embodiment may be designed through a process as below so as to have thermal insensitivity for minimizing or improving a change rate of a wavelength according to change of a temperature in a defined wavelength (e.g.: about 2000 nm 2400 nm) when the amount of currents injected into the first laser diode 111 is regular.

For example, in case the first Mach-Zehnder interferometer 151 is manufactured by using Si₃N₄ as its material, a thermo-optic coefficient of the material (e.g.: Si₃N₄) is searched, and the thermo-optic coefficient of the material (e.g.: Si₃N₄) in the wavelength band of about 2000 nm-2400 nm is measured.

Through mode simulation, dλ/dT (a changed amount of a central wavelength oscillated according to the temperature) of the first Mach-Zehnder interferometer 151 may be obtained. Through the obtained dλ/dT, a dispersion characteristic that can appear on the optical lines (e.g.: the first path 151a and the second path 151b in FIG. 15) included in the first Mach-Zehnder interferometer 151 is predicted.

Through a simulation program (e.g.: MATLAB), a condition that dλ/dT of the first path 151a and the second path 151b of the first Mach-Zehnder interferometer 151 can be offset may be obtained. In this case, the first Mach-Zehnder interferometer 151 may be designed by comprehensively considering the process or performance elements other than dλ/dT such as a process tolerance, light loss, the sizes of elements, and an interference order (m). Through this, the width W11 of the first part 151a-1 of the first path 151a of the first Mach-Zehnder interferometer 151, the length L11 of the first part 151a-1 and the length L12 of the second part 151a-2 (e.g.: 0.5 times of L11), the width W21 of the third part 151b-1 of the second path 151b, the length L21 of the third part 151b-1, and the length L22 of the fourth part 151b-2 may be set.

Referring to FIG. 16, in case the first Mach-Zehnder interferometer 151 is designed by the method explained in FIG. 15, the width W21 of the third part 151b-1 and the width of the fourth part 151b-2 of the second path 151b may be different. For example, the width W21 of the third part 151b-1 may be about 0.75 μm, and the width W22 of the fourth part 151b-2 may be about 1.8 μm. In this case, as in the E 1 part illustrated in FIG. 16, the part 151b-3 connecting the third part 151b-1 and the fourth part 151b-2 of the second path 151b may have an approximately taper shape, and thus the mode size of lights is gradually reduced and is converted to substantially coincide with the mode of the fourth part 151b-2 of the second path 151b, and accordingly, energy loss of lights can be reduced and optical defects can be improved. Likewise, as illustrated in the E2 part illustrated in FIG. 16, the part 151b-4 connecting the fourth part 151b-2 and the third part 151b-1 of the second path 151b may have an approximately taper shape.

For example, in case the first Mach-Zehnder interferometer 151 is designed by the method explained in FIG. 15, the width W11 of the first part 151a-1 and the width W12 of the second part 151a-2 of the first path 151a may be different.

According to an embodiment, the first Mach-Zehnder interferometer 151 may separate a light transmitted through the second optical line 107a into two paths, e.g., the first path 151a and the second panth 151b, and then combine them again. In this case, due to a phase difference of the first path 151a and the second panth 151b, an interference pattern (e.g.: a bright and dark pattern) may be formed. The processor 11 may analyze the periodicity of the interference pattern that appears by the first Mach-Zehnder interferometer 151, and thereby measure a wavelength of a light source more precisely.

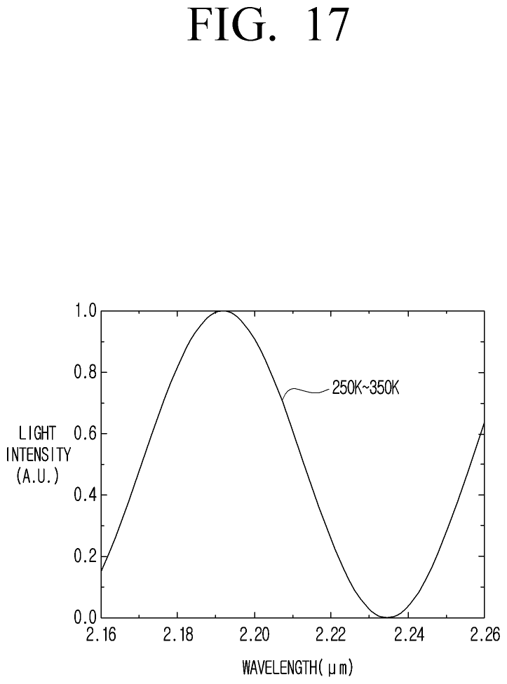

FIG. 17 is a graph illustrating spectrums for each temperature measured through a Mach-Zehnder interferometer formed on a substrate of an optical sensor according to an embodiment of the disclosure.

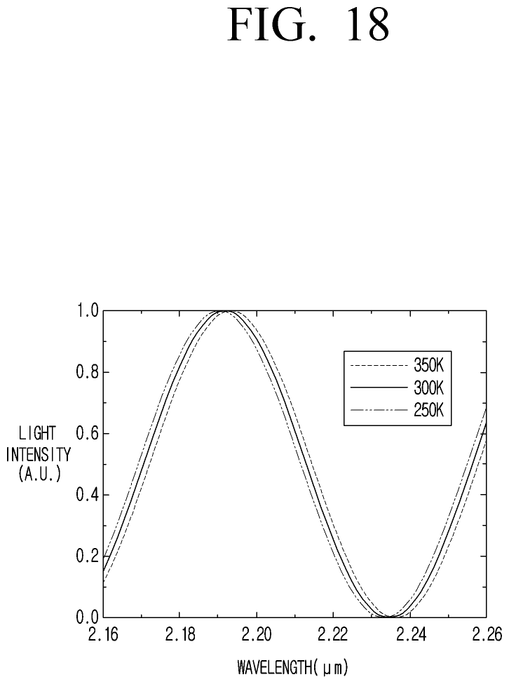

FIG. 18 is a graph illustrating spectrums for each temperature measured through a Mach-Zehnder interferometer according to an embodiment of the disclosure.

In FIGS. 17 and 18, the x axis indicates the intensity of a light emitted from a light source, and the unit of the light intensity (an arbitrary unit, A.U.) is a relative unit used in measuring the intensity of a light, and may be used in indicating a relative value in a specific experiment or measurement instead of an absolute physical amount (e.g.: watt or lumen). Also, in FIGS. 17 and 18, the y axis indicates a wavelength (μm) that a light source has.

Referring to FIG. 17, in case the first Mach-Zehnder interferometer 151 according to an embodiment is designed to have the components explained with reference to FIG. 16, a result wherein dλ/dT is close to 0 may be obtained in a defined temperature range (e.g.: about 250K-350K). Like this, the wavelength of the first Mach-Zehnder interferometer 151 does not substantially change even if the temperature increases within a specific temperature range, and thus a more correct wavelength (or fixed wavelength) can be measured.

It can be figured out that a wavelength of a Mach-Zehnder interferometer that was not designed to have the components explained with reference to FIG. 16 changes according to a temperature (e.g.: about 250K, about 300K, and about 400K) if it is based on the regular light intensity (A.U.) as in FIG. 18. That is, dλ/dT of a Mach-Zehnder interferometer may not coincide with 0.

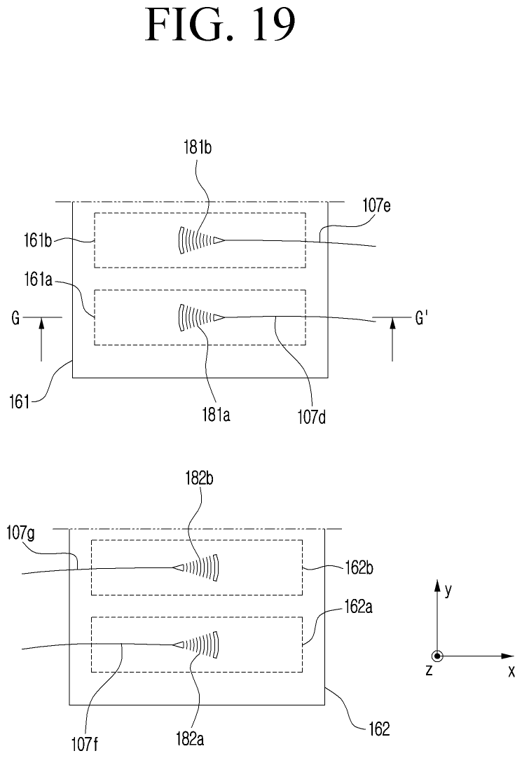

FIG. 19 is a diagram illustrating light detecting elements of an optical sensor according to an embodiment of the disclosure.

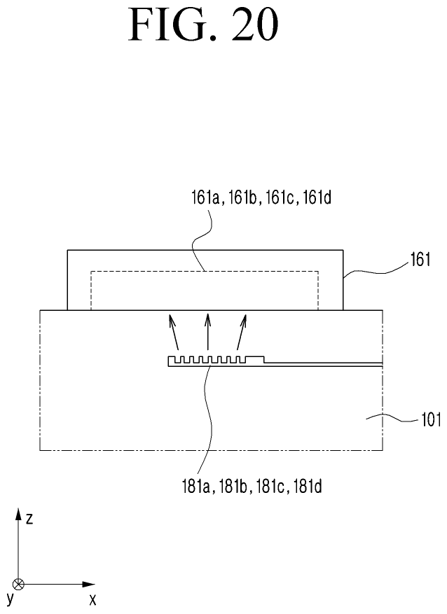

FIG. 20 is a diagram illustrating light detecting elements of an optical sensor, and is a cross-sectional view illustrated along the G-G′ line displayed in FIG. 19 according to an embodiment of the disclosure.

Referring to FIGS. 19 and 20, the first light detecting element 161 according to an embodiment may be a single photodiode on which a first active area 161a, a second active area 161b, a third active area 161c (refer to FIG. 6), and a fourth active area 161d (refer to FIG. 6) that can detect lights are arranged. The second light detecting element 162, the third light detecting element 163, and the fourth light detecting element 164 may include substantially the same structure as the first light detecting element 161. For example, the first light detecting element 161 is not limited to a single photodiode, but may include a plurality of (e.g.: four) photodiodes. Each of the second light detecting element 162, the third light detecting element 163, and the fourth light detecting element 164 may also include a plurality of photodiodes as the first light detecting element 161.

According to an embodiment, the first light detecting element 161 may be arranged on the top surface of the substrate 101. For example, the first light detecting element 161 may be arranged in a location not corresponding to the front surface 111-1 and the rear surface 111-2 of the first laser diode 111 on the substrate 101. The locations of each of the second light detecting element 162, the third light detecting element 163, and the fourth light detecting element 164 may be arranged in locations not corresponding to the front and rear surfaces of the second, third, and fourth laser diodes 112, 113, 114 in a similar manner to the first light detecting element 161 on the substrate 101.

According to an embodiment, the substrate 101 may include a first grating coupler 181a, a second grating coupler 181b, a third grating coupler 181c (refer to FIG. 6), and a fourth grating coupler 181d (refer to FIG. 6) for improving the measurement accuracy of light intensity by improving a signal-to-noise ratio (SNR) of lights detected from the first, second, third, and fourth active areas 161a, 161b, 161c, and 161d of the first light detecting element 161. For example, the first, second, third, and fourth grating couplers 181a, 181b, 181c, and 181d may be arranged in locations respectively corresponding to the direct under parts of the first, second, third, and fourth active areas 161a, 161b, 161c, and 161d of the first light detecting element 161. In this case, light emission angles of the first, second, third, and fourth grating couplers 181a, 181b, 181c, and 181d may be approximately 90 degrees with respect to the bottom surfaces of the first, second, third, and fourth active areas 161a, 161b, 161c, and 161d.

For example, the first grating coupler 181a may emit a light that has the minimum wavelength in the wavelength band of the first laser diode 111, and was transmitted through the first directional coupler 141 toward the first active area 161a of the first light detecting element 161. The second grating coupler 181b may emit a light that has the minimum wavelength in the wavelength band of the first laser diode 111, and was transmitted through the first Mach-Zehnder interferometer 151 toward the second active area 161b of the first light detecting element 161. In this case, a light incident on the first active area 161a of the first light detecting element 161 may be an optical signal that was distributed by a ratio of about 90% by the first directional coupler 141, and a light incident on the second active area 161b of the first light detecting element 161 may be an optical signal that was distributed by a ratio of about 10% by the first directional coupler 141. The first light detecting element 161 may convert optical signals respectively incident on the first active area 161a and the second active area 161b into electric signals (e.g.: a high signal (about 90%) and a low signal (about 10%)). The processor 11 may improve a signal-to-noise ratio through a complementary combination of asymmetrical electric signals received from the first light detecting element 161. For example, the processor 11 may detect a useful signal component in a high signal, and identify a noise pattern through a low signal and thereby remove at least some of the noise of the common mode through differential amplification, and may improve a signal-to-noise ratio by heightening the sensitivity for wavelength fluctuation by analyzing a change of a relative ratio of two signals. Accordingly, the processor 11 can improve the measurement accuracy for the intensity of a light (e.g.: a light of the minimum wavelength) emitted from the first laser diode 111 through the first light detecting element 161.

According to an embodiment, the fifth grating coupler 182a may emit a light that has the maximum wavelength in the wavelength band of the first laser diode 111, and was transmitted through the second directional coupler 142 (refer to FIG. 6) toward the first active area 162a of the second light detecting element 162. The sixth grating coupler 182b may emit a light that has the maximum wavelength in the wavelength band of the first laser diode 111, and was transmitted through the second Mach-Zehnder interferometer 152 (refer to FIG. 6) toward the second active area 162b of the second light detecting element 162. The processor 11 may improve a signal-to-noise ratio through a complementary combination of asymmetrical electric signals received from the second light detecting element 162. Accordingly, the processor 11 can improve the measurement accuracy for the intensity of a light (e.g.: a light of the maximum wavelength) emitted from the first laser diode 111 through the second light detecting element 162.

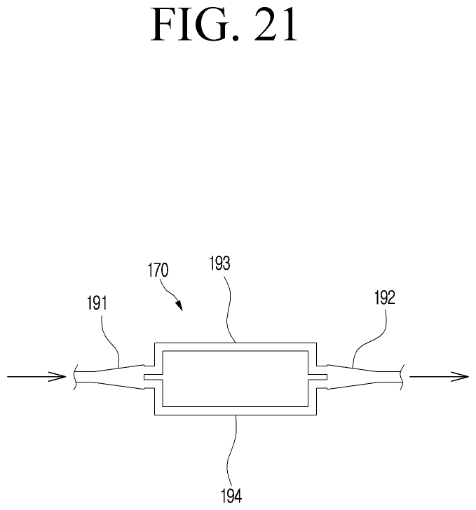

FIG. 21 is a diagram illustrating a thermal optical phase shifter of an optical sensor according to an embodiment of the disclosure.

Referring to FIG. 21, the optical sensor 100 according to an embodiment may include a thermal optical phase shifter 170 that is arranged on the first optical lines 106 and is for controlling an output of a light emitted to an object for inspection 20. For example, the thermal optical phase shifter 170 may be arranged in locations adjacent to each of the plurality of light output structures 180 (refer to the locations indicated in FIG. 6) on the plurality of first optical lines 106. The processor 11 may modulate lights emitted from the first, second, third, and fourth laser diodes 111, 112, 113, and 114 by controlling the thermal optical phase shifter 170.

Each of an input end 191 and an output end 192 of the thermal optical phase shifter 170 according to an embodiment may be used as a multi-mode interference (MMI). Between the input end 191 and the output end 192, two paths 193, 194 wherein lights are divided may be arranged. For example, in the thermal optical phase shifter 170, if a current is input into the input end 191, heat is generated in the two paths 193, 194 including metal components, and the refractive indices in the two paths 193, 194 may be changed. Through this, the thermal optical phase shifter 170 may operate as an optical switch that converts an input light to a desired output port, or selectively controls a specific wavelength.

According to an embodiment, optical signals emitted from the plurality of light output structures 180 may be converted into electric signals through a photodiode 300 (refer to FIG. 2). In this case, the electronic device 10 can improve the signal quality by filtering the amplitude and the phase by using a lock in amplifier of a specific frequency band.

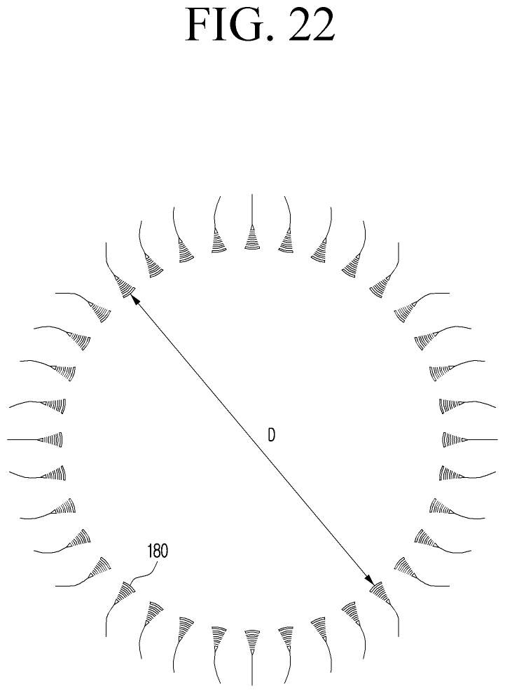

FIG. 22 is a diagram illustrating a plurality of light output structures included in a substrate according to an embodiment of the disclosure.

Referring to FIG. 22, the plurality of light output structures 180 may include a multi grating coupler structure. In this case, the multi grating coupler may be arranged within a defined diameter D such that it can be optimized for an individual wavelength to be used in a defined wavelength band (about 2000 nm-2400 nm). For example, in case the plurality of light output structures 180 consist of 36 channels, the diameter D of a circle which is the trajectory constituted by the arrangement of the plurality of light output structures 180 is about 2.52 mm, and a light emission angle may be set as about 51.5 degrees for the vertical line from the center of the circle to the object for inspection 20.

According to an embodiment, in case the components of the object for inspection 20 are measured by a non-invasive method, the processor 11 may control the driving of the first laser diode 111 so as to make the first, second, third, and fourth laser diodes 111, 112, 113, and 114 emit at least one light sequentially or in an even number or an odd number toward the object for inspection 20. In this case, in case the first, second, third, and fourth laser diodes 111, 112, 113, and 114 emit lights simultaneously, rising of the external temperature by the lights emitted from adjacent laser diodes can be improved. Accordingly, reduction of light outputs of the first, second, third, and fourth laser diodes 111, 112, 113, and 114 can be improved.

According to an embodiment, the processor 11 may monitor a change rate of the wavelengths of lights emitted from the first, second, third, and fourth laser diodes 111, 112, 113, and 114 in real time through the plurality of Mach-Zehnder interferometers 151, 152, 153, 154, 155, 156, 157, and 158, and monitor light outputs in real time through the plurality of light detecting elements 161, 162, 163, and 164, and can thereby reduce or improve errors of a blood sugar absorption rate according to changes of noises and/or wavelengths.

According to an embodiment, as the optical sensor 100 includes the plurality of laser diodes 111, 112, 113, and 114 that can cover a plurality of different wavelengths in a single chip, its structure can be simplified and accordingly, the manufacturing yield can be improved, and the manufacturing cost can be reduced. Also, the optical sensor 100 can improve the measurement performance by enhancing the measurement accuracy and reducing a signal-to-noise ratio.

Although the embodiments of the disclosure were explained by limited embodiments and drawings as above, a person having ordinary knowledge in the pertinent technical field may be able to make various amendments and modifications from the descriptions above. For example, even if the technologies explained above are performed in an order different from the explained method, and/or the components such as the system, the structure, the device, and the circuitry, etc. explained above are coupled or combined in different forms from the explained method, or replaced or substituted by different components or equivalents, an appropriate result could be achieved. Therefore, other implementations, other embodiments, and equivalents to the scope of the claims would belong to the scope of the claims that will be described below.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An optical sensor for sensing a biometric signal, the optical sensor comprising:
a substrate including a groove;
a laser diode which is inserted into the groove, and includes an active layer, and a plurality of lights of different wavelengths that are emitted from a plurality of light-emitting points of the active layer;
a plurality of waveguides which are arranged inside the substrate, and are configured to guide the plurality of lights emitted from the active layer of the laser diode;
a plurality of first optical lines which are arranged inside the substrate, and of which one end is connected to the plurality of waveguides and the other end is connected to a plurality of light output structures, and which transmit the plurality of lights guided along the plurality of waveguides to the plurality of light output structures;
second optical lines which are arranged inside the substrate, and are branched from one of the plurality of first optical lines; and
a light detecting element which is arranged on the substrate, and detects light transmitted along the second optical lines,
wherein the laser diode is configured to be inserted into the groove such that heights of the plurality of light-emitting points of the active layer are respectively aligned with heights of the plurality of waveguides.

2. The optical sensor of claim 1, wherein the plurality of light output structures are arranged to gather in a defined area of the substrate.

3. The optical sensor of claim 2, further comprising:
a lens arranged to be spaced apart from the substrate,
wherein the lens is configured to correspond to the defined area of the substrate.

4. The optical sensor of claim 1, wherein the groove of the substrate comprises:
a support which supports the laser diode such that the heights of the plurality of light-emitting points of the active layer are respectively aligned with the heights of the plurality of waveguides.

5. The optical sensor of claim 4, wherein the support comprises:
a first stopper and a second stopper which are arranged to be spaced apart from each other and support a lower surface of the laser diode; and
a height of an upper end of the first stopper is the same as the height of an upper end of the second stopper.

6. The optical sensor of claim 5,
wherein the substrate comprises:
a plurality of first pads which are arranged between the first stopper and the second stopper, and are electrically connected to each of a plurality of first electrodes arranged on a lower surface of the laser diode, and
the plurality of first electrodes of the laser diode and the plurality of first pads of the substrate are bonded by a solder,
wherein a length which is a sum of a thickness of the first electrodes of the laser diode, a thickness of the plurality of first pads of the substrate, and
wherein a thickness of the solder corresponds to an interval between the lower surface of the laser diode on which the first electrodes are arranged and a bottom surface of the substrate.

7. The optical sensor of claim 6, wherein the laser diode comprises:
a first semiconductor layer;
a second semiconductor layer;
the active layer which is positioned between the first semiconductor layer and the second semiconductor layer;
a passivation layer which covers the second semiconductor layer; and
a metal layer which covers the passivation layer, and is connected to a part of the second semiconductor layer, and is connected to the plurality of first electrodes of the laser diode.

8. The optical sensor of claim 1, wherein a center of each of the plurality of waveguides and a center of each of the plurality of light-emitting points of the active layer are positioned on the same plane.

9. The optical sensor of claim 1, wherein a space of a front surface of the laser diode is configured so as to be spaced apart from a light incident surface of the substrate facing the front surface of the laser diode by a defined interval.

10. The optical sensor of claim 9,
wherein each of the plurality of waveguides comprises:
a first part adjacent to the light incident surface, and
a second part arranged farther than the first part from the light incident surface, and
wherein the first part of each of the plurality of waveguides is spaced apart from the light incident surface of the substrate in a direction of getting far from the front surface of the laser diode, and includes an inverse taper shape whose width gradually becomes wider from the light incident surface of the substrate toward the second part.

11. The optical sensor of claim 6, wherein, in a space between the laser diode and the substrate, an epoxy layer which diffusively reflects a light reflected from a light incident surface of the substrate to restrict the light from being incident on a front surface of the laser diode is arranged.

12. The optical sensor of claim 4,
wherein the laser diode comprises:
a plurality of laser diodes emitting light of different wavelength bands, and
wherein the support further comprises:
a plurality of additional supports on which the plurality of laser diodes rest.

13. The optical sensor of claim 1, wherein the substrate comprises:
a directional coupler which distributes light transmitted along the second optical lines in a defined ratio;
a Mach-Zehnder interferometer which controls a light output by using an interference effect that occurs when a light transmitted along the second optical lines and a light distributed by the directional coupler are coupled; and
a first grating coupler which is arranged on a lower side of the light detecting element and guides a light that passed through the Mach-Zehnder interferometer to emit the light toward the light detecting element.

14. The optical sensor of claim 1,
wherein each of the plurality of light output structures comprises:
a second grating coupler, and
a plurality of thermal optical phase shifters arranged on the plurality of first optical lines, and
wherein the plurality of thermal optical phase shifters are configured to thermally control light transmitted to the plurality of light output structures to change a strength of light emitted from the plurality of light output structures.

15. An electronic device comprising:
a housing including a light transmitting material;
an optical sensor which is arranged on an inner side of the housing and emits a light toward an object for inspection on an outer side of the housing;
an optical interface which introduces the light emitted from the optical sensor into the object for inspection; and
a photodiode which detects a light reflected on the object for inspection,
wherein the optical sensor comprises:
a laser diode which includes an active layer that emits light of different wavelengths in a defined wavelength band,
a substrate which includes a groove into which the laser diode is inserted, a plurality of waveguides which respectively guides light emitted from a front surface of the laser diode, a plurality of first optical lines which are respectively connected to the plurality of waveguides and guides light transmitted along the plurality of waveguides to a plurality of light output structures, and second optical lines branched from at least one first optical line among the plurality of first optical lines,
a light detecting element which is arranged on the substrate and detects light transmitted along the first optical lines and light transmitted along the second optical lines,
a Mach-Zehnder interferometer which is arranged between the second optical lines and the light detecting element, and measures a strength and a defined wavelength of the light transmitted along the second optical lines, and
a thermal optical phase shifter which is arranged on the first optical lines and is configured to thermally control light transmitted to an outputter to change the strength of the light emitted from the outputter, and
wherein the substrate comprises:
a support on which the laser diode rests such that a height of the active layer of the laser diode is aligned with heights of the plurality of waveguides.

16. The electronic device of claim 15, wherein the plurality of light output structures are arranged to gather in a defined area of the substrate.

17. The electronic device of claim 15, further comprising:
a lens arranged to be spaced apart from the substrate,
wherein the lens is configured to correspond to a defined area of the substrate.

18. The electronic device of claim 15, wherein the groove of the substrate comprises:
a support which supports the laser diode such that heights of a plurality of light-emitting points of the active layer are respectively aligned with the heights of the plurality of waveguides.

19. The electronic device of claim 15, wherein the plurality of light output structures include a multi grating coupler structure.

20. The electronic device of claim 19, wherein the multi grating coupler structure is disposed within a defined diameter such that it is optimized for an individual wavelength to be used in a defined wavelength band.
